(19) United States
(12) Patent Application Publication
(10) Pub. No.: US 2014/0020760 A1
(43) Pub. Date: Jan. 23, 2014

(54) METHOD OF PRODUCING ORGANIC PHOTOELECTRIC CONVERSION DEVICE

(71) Applicants: Takehito Kato, Oyama-shi (JP); Ken Yoshimura, Tsukuba-shi (JP)

(72) Inventors: Takehito Kato, Oyama-shi (JP); Ken Yoshimura, Tsukuba-shi (JP)

(73) Assignee: SUMITOMO CHEMICAL COMPANY, LIMITED, Chuo-ku, Tokyo (JP)

(21) Appl. No.: 13/982,504

(22) PCT Filed: Feb. 24, 2012
(86) PCT No.: PCT/JP2012/055302

§ 371 Date: Oct. 7, 2013

(30) Foreign Application Priority Data
Feb. 28, 2011 (JP) 2011-041204

(51) Int. Cl. H01L 51/00

(52) U.S. Cl. CPC H01L 51/0036; H01L 51/0001
USPC 136/263; 252/500; 438/93

(57) ABSTRACT

An organic photoelectric conversion device excellent in photoelectric conversion efficiency can be produced, by forming an active layer using a solution containing a polymer compound and a deoxidized solvent in a method of producing an organic photoelectric conversion device having a pair of electrodes and the active layer containing the polymer compound disposed between the pair of electrodes.

### TECHNICAL FIELD

The present invention relates to a method of producing an organic photoelectric conversion device.

### BACKGROUND ART

Organic photoelectric conversion devices have merits that the number of organic layers in the device can be reduced, the organic layers can be produced by a printing method, and the like, and thus can be produced simply at low cost as compared with inorganic photoelectric conversion devices. However, poor photoelectric conversion efficiency of organic photoelectric conversion devices has interfered with practical application thereof.

There is a suggestion on an organic photoelectric conversion device having an active layer formed by using a solution containing a polymer compound P3HT and o-dichlorobenzene (JP-A No. 2009-158734).

The above-described organic photoelectric conversion device, however, has no sufficient photoelectric conversion efficiency.

### SUMMARY OF THE INVENTION

The present invention provides a method of producing an organic photoelectric conversion device having high photoelectric conversion efficiency.

That is, the present invention provides a method of producing an organic photoelectric conversion device having a pair of electrodes and an active layer containing a polymer compound disposed between the pair of electrodes, comprising a step of forming the active layer using a solution containing the polymer compound and a deoxidized solvent.

Further, the present invention provides use of a solution containing a polymer compound and a solvent and having an oxygen weight concentration of 25 ppm or less, particularly 10 ppm or less, for the material of an organic photoelectric conversion device.

### BRIEF EXPLANATION OF DRAWINGS

FIG. 1 is a view showing one example of the layered structure of an organic photoelectric conversion device according to the present invention. FIGS. 2 and 3 area view showing another example of the layered structure of an organic photoelectric conversion device according to the present invention.

The number 10 represents an organic photoelectric conversion device, 20 represents a substrate, 32 represents a first electrode, and 34 represents a second electrode. The number 40 represents an active layer, 42 represents a first active layer, 44 represents a second active layer, 52 represents a first intermediate layer, and 54 represents a second intermediate layer.

### MODES FOR CARRYING OUT THE INVENTION

In the method of producing an organic photoelectric conversion device of the present invention, the solution used for forming an active layer (hereinafter, this solution is referred to as organic photoelectric conversion device material) can be obtained by subjecting a solution containing a polymer compound and a solvent to a deoxidizing treatment, or can also be obtained by subjecting a solvent to a deoxidizing treatment, then, mixing the solvent with a polymer compound.

The deoxidizing treatment can be carried out, for example, by introducing nitrogen into a solution containing a polymer compound and a solvent, or into a solvent. Introduction of nitrogen into a solvent is carried out, for example, by inserting a tube into a solvent and blowing a nitrogen gas therethrough.

In the case of introducing nitrogen into 30 mL of a solvent in a glove box containing an atmosphere having a nitrogen concentration adjusted to 1% or less, the time of introducing nitrogen is preferably 5 minutes or more, more preferably 15 minutes or more, further preferably 30 minutes or more. When the amount of a solvent is larger than 30 mL, it is preferable that the time of introducing nitrogen is longer.

In the present invention, it is preferable that a polymer compound is exposed to nitrogen under a nitrogen atmosphere before mixing the polymer compound and a solvent, from the standpoint of lowering of the oxygen weight concentration in an organic photoelectric conversion device material. As the nitrogen atmosphere, a glove box having an oxygen concentration adjusted to 1% or less is mentioned, and it is preferable that a polymer compound is allowed to stand still for 12 hours or more in the glove box. When the organic photoelectric conversion device material contains an electron donating compound or an electron acceptive compound, it is preferable that the electron donating compound or the electron acceptive compound is exposed to nitrogen under a nitrogen atmosphere.

The step of forming an active layer using an organic photoelectric conversion device material is preferably a step of forming an active layer by coating an organic photoelectric conversion device material on one electrode.

Exemplified as the coating method are a spin coat method, a casting method, a micro gravure coat method, a gravure coat method, a bar coat method, a roll coat method, a wire bar coat method, a dip coat method, a spray coat method, a screen printing method, a gravure printing method, a flexo printing method, an offset printing method, an inkjet printing method, a dispenser printing method, a nozzle coat method, a capillary coat method and the like. Of them, a spin coat method, a flexo printing method, a gravure printing method, an inkjet printing method and a dispenser printing method are preferable, a spin coat method is more preferable.

The organic photoelectric conversion device material according to the present invention contains a polymer compound and a solvent, and has an oxygen weight concentration of usually 25 ppm or less. The organic photoelectric conversion device material is a material used for production of an organic photoelectric conversion device, and may be a solution, or may be a dispersion containing a polymer compound dispersed in a solvent.

The oxygen weight concentration in the organic photoelectric conversion device material is preferably 20 ppm or less, more preferably 10 ppm or less, further preferably 5 ppm or less, from the standpoint of enhancement of photoelectric conversion efficiency of an organic photoelectric conversion device to be produced. It is most preferably 1 ppm or less, from the standpoint of enhancement of photoelectric conversion efficiency.

When the oxygen weight concentration in the organic photoelectric conversion device material is high, oxygen in the device captures electrons and holes after charge separation, after producing the organic photoelectric conversion device, and resultantly, photocurrent of the device lowers and fill factor (FF) thereof lowers, leading to decrease in photoelectric conversion efficiency.

The oxygen weight concentration in the organic photoelectric conversion device material can be measured by gas chromatography.

The polymer compound as an electron donating compound or an electron acceptive compound contained in an active layer is not particularly restricted, and determined relatively according to the energy level of the compound. The polymer compound includes polymer compounds containing a cyclic structure shown below

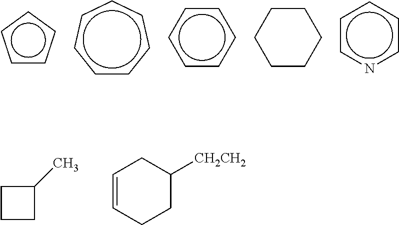

and a structure of methylcyclobutane, 4-ethylcyclohexane, xylene, styrene, ethylbenzene, thiophene, imidazole, thiazole, pyrrole, oxazole and the like. Also mentioned are polymer compounds containing a structure of ethyleneimine, ethylene oxide, ethylene sulfide, acetylene oxide, acetylene sulfide, azacyclobutane 1,3-propylene oxide, trimethylene sulfide, oxetium ion, thietium ion, pyrrolidine, tetrahydrofuran, tetrahydrothiophene, pyrrole, furan, thiophene, piperidine, tetrahydropyran, tetrahydrothiopyran, thiapyran, hexamethyleneimine, hexamethylene oxide, hexamethylene sulfide, azatropilidene, oxycycloheptatriene, thiotropilidene and the like. Further mentioned are polymer compounds containing a structure of anthracene, phenanthracene, tetracene, chrysene, pyrene, triphenylene, tetraphene, pyrene, pentacene, picene, perylene, indene, fluorene, naphthalene, benzoanthracene, dibenzophenanthracene, benzothiophene, quinoxaline, indole, isoindole, benzoimidazole, purine, quinoline, isoquinoline, cinnoline, pteridine, chromene, isochromene, acridine, xanthene, carbazole, porphyrin, chlorin, corrin and the like.

Examples of the polymer compound contained in an active layer include polymer compounds having a structural unit represented by the formula (1).

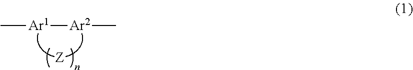

[wherein, Ar¹ and Ar² are the same or mutually different and represent a tri-valent aromatic group. Z represents —O—, —S—, —C(═O)—, —CR¹R²—, —S(═O)—, —SO₂—, —Si(R³)(R⁴)—, —N(R⁵)—, —B(R⁶)—, —P(R⁷)— or P(═O)(R⁸)—. R¹, R², R³, R⁴, R⁵, R⁶, R⁷ and R⁸ are the same or mutually different and represent a hydrogen atom, a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an imide group, an imino group, an amino group, a substituted amino group, a substituted silyl group, a substituted silyloxy group, a substituted silylthio group, a substituted silylamino group, a mono-valent heterocyclic group, a heterocyclicoxy group, a heterocyclicthio group, an arylalkenyl group, an arylalkynyl group, a carboxyl group or a cyano group. n represents 1 or 2. When n is 2, two Zs may be the same or different.].

The polymer compound having a structural unit represented by the formula (1) may be a polymer compound further containing a structural unit represented by any of the following formulae (2-1) to (2-10).

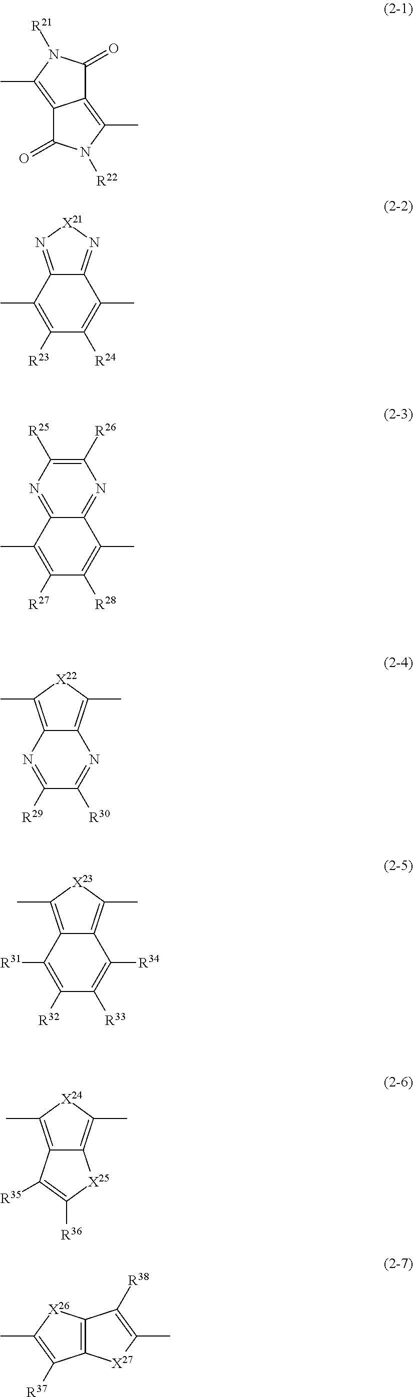

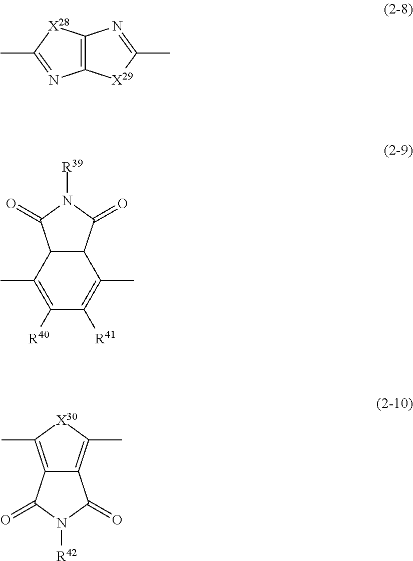

[wherein, R²¹ to R⁴² represent each independently a hydrogen atom or a substituent. X²¹ to X³⁰ represent each independently a sulfur atom, an oxygen atom or a selenium atom.]

Examples of the substituent represented by R²¹ to R⁴² include halogen atoms, alkyl groups optionally having a substituent, alkoxy groups optionally having a substituent, alkylthio groups optionally having a substituent, aryl groups, aryloxy groups, arylthio groups, arylalkyl groups, arylalkoxy groups, arylalkylthio groups, arylalkenyl groups, arylalkynyl groups, amino groups, substituted amino groups, silyl groups, substituted silyl groups, acyl groups, acyloxy groups, amide groups, heterocyclic groups, carboxy groups optionally having a substituent, a nitro group and a cyano group.

R²¹, R²² and R³⁵ represent preferably an alkyl group optionally having a substituent, an alkoxy group optionally having a substituent or an alkylthio group optionally having a substituent, more preferably an alkyl group optionally having a substituent or an alkoxy group optionally having a substituent, further preferably an alkyl group optionally having a substituent. R²¹, R²², R³⁵, R³⁹ and R⁴² represent preferably a branched alkyl group, from the standpoint of enhancement of solubility of a polymer compound of the present invention.

R²³, R²⁴, R²⁷, R²⁸, R³¹, R³², R³³, R³⁴, R³⁷, R³⁸, R⁴⁰ and R⁴¹ represent preferably a halogen atom or a hydrogen atom, more preferably a fluorine atom or a hydrogen atom, further preferably a hydrogen atom.

R²⁵, R²⁶, R²⁹ and R³⁰ represent preferably a hydrogen atom, a halogen atom, an alkyl group optionally having a substituent, an aryl group or an arylalkyl group, more preferably a hydrogen atom or an arylalkyl group.

R³⁶ represents preferably a hydrogen atom, a halogen atom, an acyl group or an acyloxy group, more preferably an acyl group or an acyloxy group.

X²¹ to X³⁰ represent each independently a sulfur atom, an oxygen atom or a selenium atom, and from the standpoint of enhancing short circuit current density of a photoelectric conversion device in the present invention, preferably a sulfur atom or an oxygen atom, more preferably a sulfur atom.

In the present invention, the polymer compound preferably has a structural unit represented by the formula (2-1), the formula (2-2), the formula (2-3) or the formula (2-10), more preferably has a structural unit represented by the formula (2-1), the formula (2-2) or the formula (2-10), further preferably has a structural unit represented by the formula (2-1) or the formula (2-10), particularly preferably has a structural unit represented by the formula (2-10), from the standpoint of enhancing short circuit current density of a photoelectric conversion device.

In another aspect, the polymer compound having a structural unit represented by the formula (1) may be a polymer compound further containing a structural unit represented by the formula (2).

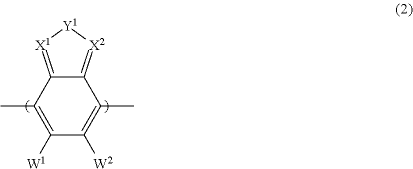

[wherein, X¹ and X² are the same or mutually different and represent a nitrogen atom or ═CH—. Y¹ represents a sulfur atom, an oxygen atom, a selenium atom, —N(R⁴³)— or CR⁴⁴═CR⁴⁵. R⁴³, R⁴⁴ and R⁴⁵ are the same or mutually different and represent a hydrogen atom or a substituent. W¹ and W² are the same or mutually different and represent a cyano group, a mono-valent organic group having a fluorine atom, a halogen atom or a hydrogen atom.].

In the formula (2), X¹ and X² represent a nitrogen atom or ═CH—, and it is preferable that at least one of X¹ and X² represents a nitrogen atom, it is preferable that both X¹ and X² are a nitrogen atom.

The mono-valent organic group having a fluorine atom represented by W¹ and W² in the formula (2) includes fluorinated aryl groups, fluorinated alkyl groups, fluorinated alkylthio groups, fluorinated sulfonyl groups, fluorinated acetyl groups and the like. The fluorinated alkyl group includes a fluoromethyl group and the like. The fluorinated aryl group includes a fluorophenyl group and the like. Here, the halogen atom includes a fluorine atom, a chlorine atom, a bromine atom and an iodine atom.

From the standpoint of absorption intensity and solubility of the polymer compound containing a structural unit represented by the formula (2), it is preferable that W¹ and W² are a fluorine atom.

In the formula (2), Y¹ represents a sulfur atom, an oxygen atom, a selenium atom, —N(R⁴⁶)— or CR⁴⁷═CR⁴⁸, R⁴⁶, R⁴⁷ and R⁴⁸ are the same or mutually different and represent a hydrogen atom, a halogen atom or substituent. Here, the substituent includes alkyl groups, alkoxy groups, alkylthio groups, aryl groups, aryloxy groups, arylthio groups, arylalkyl groups, arylalkyloxy groups, arylalkylthio groups, acyl groups, acyloxy groups, amide groups, imide groups, imino groups, amino groups, substituted amino groups, substituted silyl groups, substituted silyloxy groups, substituted silylthio groups, substituted silylamino groups, mono-valent heterocyclic groups, heterocyclicoxy groups, heterocyclicthio groups, arylalkenyl groups, arylalkynyl groups, a carboxyl group and a cyano group.

From the standpoint of absorption intensity and solubility of the polymer compound containing a structural unit represented by the formula (1), it is preferable that Y¹ is a sulfur atom or an oxygen atom.

In the present invention, the halogen atom is a fluorine atom, a chlorine atom, a bromine atom or an iodine atom.

In the present invention, the alkyl group may be linear, branched or cyclic. The alkyl group has a number of carbon atoms of usually 1 to 30. Specific examples of the alkyl group include linear alkyl groups such as a methyl group, an ethyl group, a n-propyl group, an isopropyl group, a n-butyl group, an isobutyl group, a sec-butyl group, a tert-butyl group, a n-pentyl group, an isopentyl group, a 2-methylbutyl group, a 1-methylbutyl group, a n-hexyl group, an isohexyl group, a 3-methylpentyl group, a 2-methylpentyl group, a 1-methylpentyl group, a heptyl group, an octyl group, an isooctyl group, a 2-ethylhexyl group, a 3,7-dimethyloctyl group, a nonyl group, a decyl group, an undecyl group, a dodecyl group, a tetradecyl group, a hexadecyl group, an octadecyl group, an eicosyl group and the like, and cycloalkyl groups such as a cyclopentyl group, a cyclohexyl group, an adamantyl group and the like.

In the present invention, the alkoxy group may be linear, branched or cyclic. The alkoxy group has a number of carbon atoms of usually 1 to 20. Specific examples of the alkoxy group include a methoxy group, an ethoxy group, a propoxy group, an isopropoxy group, a butoxy group, an isobutoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group and a lauryloxy group, and specific examples of the substituted alkoxy group include fluorinated alkoxy groups having a number of carbon atoms of 1 to 20 such as a trifluoromethoxy group, a pentafluoroethoxy group, a perfluorobutoxy group, a perfluorohexyl group, a perfluorooctyl group, a methoxymethyloxy group, a 2-methoxyethyloxy group and the like.

In the present invention, the alkylthio group may be linear or branched, and may also be a cycloalkylthio group. The alkylthio group has a number of carbon atoms of usually 1 to 20, and specific examples of the alkylthio group include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group and a trifluoromethylthio group.

In the present invention, the aryl group has a number of carbon atoms of usually 6 to 60. Specific examples of the aryl group include a phenyl group, C1 to C12 alkoxyphenyl groups (The C1 to C12 alkyl denotes an alkyl having 1 to 12 carbon atoms. The C1 to C12 alkyl is preferably a C1 to C8 alkyl, more preferably a C1 to C6 alkyl. The C1 to C8 alkyl denotes an alky having 1 to 8 carbon atoms, and the C1 to C6 alkyl denotes an alkyl having 1 to 6 carbon atoms. Specific examples of the C1 to C12 alkyl, the C1 to C8 alkyl and the C1 to C6 alkyl include those explained and exemplified for the above-described alkyl group. The same shall apply hereinafter.), C1 to C12 alkylphenyl groups, a 1-naphthyl group, a 2-naphthyl group and a pentafluorophenyl group.

In the present invention, the aryloxy group has a number of carbon atoms of usually 6 to 60. Specific examples of the aryloxy group include a phenoxy group, C1 to C12 alkoxyphenoxy groups, C1 to C12 alkylphenoxy groups, a 1-naphthyloxy group, a 2-naphthyloxy group and a pentafluorophenoxy group.

In the present invention, the arylthio group has a number of carbon atoms of usually 6 to 60. Specific examples of the arylthio group include a phenylthio group, C1 to C12 alkoxyphenylthio groups, C1 to C12 alkylphenylthio groups, a 1-naphthylthio group and a 2-naphthylthio group, and specific examples of the substituted arylthio group include a pentafluorophenylthio group.

In the present invention, the arylalkyl group has a number of carbon atoms of usually 7 to 60. Specific examples of the arylalkyl group include phenyl-C1 to C12 alkyl groups, C1 to C12 alkoxyphenyl-C1 to C12 alkyl groups, C1 to C12 alkylphenyl-C1 to C12 alkyl groups, 1-naphthyl-C1 to C12 alkyl groups and 2-naphthyl-C1 to C12 alkyl groups.

In the present invention, the arylalkoxy group has a number of carbon atoms of usually 7 to 60. Specific examples of the arylalkoxy group include phenyl-C1 to C12 alkoxy groups, C1 to C12 alkoxyphenyl-C1 to C12 alkoxy groups, C1 to C12 alkylphenyl-C1 to C12 alkoxy groups, 1-naphthyl-C1 to C12 alkoxy groups and 2-naphthyl-C1 to C12 alkoxy groups.

In the present invention, the arylalkylthio group has a number of carbon atoms of usually 7 to 60. Specific examples of the arylalkylthio group include phenyl-C1 to C12 alkylthio groups, C1 to C12 alkoxyphenyl-C1 to C12 alkylthio groups, C1 to C12 alkylphenyl-C1 to C12 alkylthio groups, 1-naphthyl-C1 to C12 alkylthio groups and 2-naphthyl-C1 to C12 alkylthio groups.

In the present invention, the acyl group has a number of carbon atoms of usually 2 to 20. Specific examples of the acyl group include an acetyl group, a propionyl group, a butyryl group, an isobutyryl group, a pivaloyl group, a benzoyl group, a trifluoroacetyl group and a pentafluorobenzoyl group.

In the present invention, the acyloxy group has a number of carbon atoms of usually 2 to 20. Specific examples of the acyloxy group include an acetoxy group, a propionyloxy group, a butyryloxy group, an isobutyryloxy group, a pivaloyloxy group, a benzoyloxy group, a trifluoroacetyloxy group and a pentafluorobenzoyloxy group.

The amide group has a number of carbon atoms of usually 1 to 20. The amide group means a group obtained by removing from an acid amide a hydrogen atom linked to its nitrogen atom. Specific examples of the amide group include a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group and a dipentafluorobenzamide group.

In the present invention, the imide group means a group obtained by removing from an acid imide a hydrogen atom linked to its nitrogen atom. Specific examples of the imide group include a succinimide group and a phthalic imide group.

In the present invention, the substituted amino group has a number of carbon atoms of usually 1 to 40. Specific examples of the substituted amino group include a methylamino group, a dimethylamino group, an ethylamino group, a diethylamino group, a propylamino group, a dipropylamino group, an isopropylamino group, a diisopropylamino group, a butylamino group, an isobutylamino group, a tert-butylamino group, a pentylamino group, a hexylamino group, a cyclohexylamino group, a heptylamino group, an octylamino group, a 2-ethylhexylamino group, a nonylamino group, a decylamino group, a 3,7-dimethyloctylamino group, a laurylamino group, a cyclopentylamino group, a dicyclopentylamino group, a cyclohexylamino group, a dicyclohexylamino group, a pyrrolidyl group, a piperidyl group, a ditrifluoromethylamino group, a phenylamino group, a diphenylamino group, C1 to C12 alkyloxyphenylamino groups, di(C1 to C12 alkoxyphenyl)amino groups, di(C1 to C12 alkylphenyl)amino groups, a 1-naphthylamino group, a 2-naphthylamino group, a pentafluorophenylamino group, a pyridylamino group, a pyridazinylamino group, a pyrimidylamino group, a pyrazylamino group, a triazylamino group, phenyl-C1 to C12 alkylamino groups, C1 to C12 alkyloxyphenyl-C1 to C12 alkylamino groups, C1 to C12 alkylphenyl-C1 to C12 alkylamino groups, di(C1 to C12 alkoxyphenyl-C1 to C12 alkyl)amino groups, di(C1 to C12 alkylphenyl-C1 to C12 alkyl)amino groups, 1-naphthyl-C1 to C12 alkylamino groups and 2-naphthyl-C1 to C12 alkylamino groups.

In the present invention, the substituted silyl group includes, for example, a trimethylsilyl group, a triethylsilyl group, a tri-n-propylsilyl group, a triisopropylsilyl group, a tert-butyldimethylsilyl group, a triphenylsilyl group, a tri-p-xylylsilyl group, a tribenzylsilyl group, a diphenylmethylsilyl group, a tert-butyldiphenylsilyl group and a dimethylphenylsilyl group.

In the present invention, the substituted silyloxy group includes, for example, a trimethylsilyloxy group, a triethylsilyloxy group, a tri-n-propylsilyloxy group, a triisopropylsilyloxy group, a tert-butyldimethylsilyloxy group, a triphenylsilyloxy group, a tri-p-xylylsilyloxy group, a tribenzylsilyloxy group, a diphenylmethylsilyloxy group, a tert-butyldiphenylsilyloxy group and a dimethylphenylsilyloxy group.

In the present invention, the substituted silylthio group includes, for example, a trimethylsilylthio group, a triethylsilylthio group, a tri-n-propylsilylthio group, a triisopropylsilylthio group, a tert-butyldimethylsilylthio group, a triphenylsilylthio group, a tri-p-xylylsilylthio group, a tribenzylsilylthio group, a diphenylmethylsilylthio group, a tert-butyldiphenylsilylthio group and a dimethylphenylsilylthio group.

In the present invention, the substituted silylamino group includes, for example, a trimethylsilylamino group, a triethylsilylamino group, a tri-n-propylsilylamino group, a triisopropylsilylamino group, a tert-butyldimethylsilylamino group, a triphenylsilylamino group, a tri-p-xylylsilylamino group, a tribenzylsilylamino group, a diphenylmethylsilylamino group, a tert-butyldiphenylsilylamino group, a dimethylphenylsilylamino group, a di(trimethylsilyl)amino group, a di(triethylsilyl)amino group, a di(tri-n-propylsilyl)amino group, a di(triisopropylsilyl)amino group, a di(tert-butyldimethylsilyl)amino group, a di(triphenylsilyl)amino group, a di(tri-p-xylylsilyl)amino group, a di(tribenzylsilyl)amino group, a di(diphenylmethylsilyl)amino group, a di(tert-butyldiphenylsilyl)amino group and a di(dimethylphenylsilyl)amino group.

In the present invention, the mono-valent heterocyclic group includes groups obtained by removing one hydrogen atom from heterocyclic compounds such as furan, thiophene, pyrrole, pyrroline, pyrrolidine, oxazole, isooxazole, thiazole, isothiazole, imidazole, imidazoline, imidazolidine, pyrazole, pyrazoline, pyrazolidine, furazan, triazole, thiadiazole, oxadiazole, tetrazole, pyran, pyridine, piperidine, thiopyran, pyridazine, pyrimidine, pyrazine, piperazine, morpholine, triazine, benzofuran, isobenzofuran, benzothiophene, indole, isoindole, indolizine, indoline, isoindoline, chromene, chromane, isochromane, benzopyran, quinoline, isoquinoline, quinolizine, benzoimidazole, benzothiazole, indazole, naphthyridine, quinoxaline, quinazoline, quinazolidine, cinnoline, phthalazine, purine, pteridine, carbazole, xanthene, phenanthridine, acridine, β-carboline, perimidine, phenanthroline, thianthrene, phenoxathiin, phenoxazine, phenothiazine, phenazine and the like. The mono-valent heterocyclic group is preferably a mono-valent aromatic heterocyclic group.

In the present invention, the heterocyclicoxy group includes groups represented by the formula (4) obtained by linking an oxygen atom to the above-described mono-valent heterocyclic groups. The heterocyclicthio group includes groups represented by the formula (5) obtained by linking a sulfur atom the above-described mono-valent heterocyclic groups.

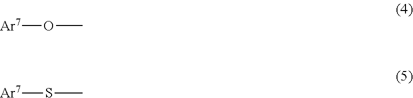

In the formula (4) and the formula (5), Ar⁷ represents a mono-valent heterocyclic group.

In the present invention, the heterocyclicoxy group has a number of carbon atoms of usually 2 to 60. Specific examples of the heterocyclicoxy group include a thienyloxy group, C1 to C12 alkylthienyloxy groups, a pyrrolyloxy group, a furyloxy group, a pyridyloxy group, C1 to C12 alkylpyridyloxy groups, an imidazolyloxy group, a pyrazolyloxy group, a triazolyloxy group, an oxazolyloxy group, a thiazoleoxy group and a thiadiazoleoxy group.

In the present invention, the heterocyclicthio group has a number of carbon atoms of usually 2 to 60. Specific examples of the heterocyclicthio group include a thienylmercapto group, C1 to C12 alkylthienylmercapto groups, a pyrrolylmercapto group, a furylmercapto group, a pyridylmercapto group, C1 to C12 alkylpyridylmercapto groups, an imidazolylmercapto group, a pyrazolylmercapto group, a triazolylmercapto group, an oxazolylmercapto group, a thiazolemercapto group and a thiadiazolemercapto group.

In the present invention, the arylalkenyl group has a number of carbon atoms of usually 8 to 20, and specific examples of the arylalkenyl group include a styryl group.

In the present invention, the arylalkynyl group has a number of carbon atoms of usually 8 to 20, and specific examples of the arylalkynyl group include a phenylacetylenyl group.

The structural unit represented by the formula (2) is preferably a structural unit represented by the formula (2-1) or a structural unit represented by the formula (2-2).

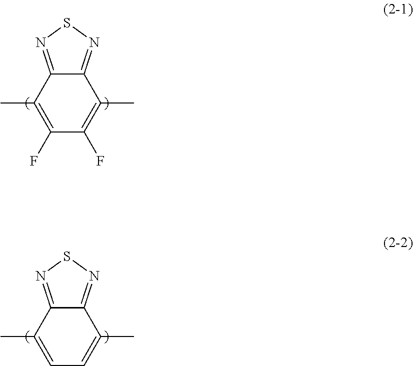

The polymer compound of the present invention may further contain a structural unit represented by the formula (2′), in addition to a structural unit represented by the formula (1).

Ar³ (2′)

[wherein, Ar³ represents an arylene group or a heteroarylene group different from the structural unit represented by the formula (1).].

In the present invention, the arylene group includes, for example, a phenylene group, a naphthalenediyl group, an anthracenediyl group, a pyrenediyl group and a fluorenediyl group. The heteroarylene group includes, for example, a furandiyl group, a pyrrolediyl group and a pyridinediyl group.

Preferable embodiments of the structural unit represented by the formula (1) are groups represented by the formula (3).

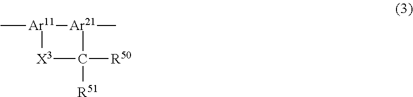

In the formula (3), Ar¹¹ and Ar²¹ are the same or mutually different and represent a tri-valent aromatic group. X³ represents —O—, —S—, —C(═O)—, —S(═O)—, —SO₂—, —Si(R⁹)(R¹⁰)—, —N(R¹¹)—, —B(R¹²)—, —P(R¹³)— or P(═O)(R¹⁴)—.

R⁹, R¹⁰, R¹¹, R¹², R¹³ and R¹⁴ are the same or mutually different and represent a hydrogen atom, a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an imide group, an imino group, an amino group, a substituted amino group, a substituted silyl group, a substituted silyloxy group, a substituted silylthio group, a substituted silylamino group, a mono-valent heterocyclic group, a heterocyclicoxy group, a heterocyclicthio group, an arylalkenyl group, an arylalkynyl group, a carboxyl group or a cyano group. R⁵⁰ and R⁵¹ are the same or different and represent a hydrogen atom, a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an imide group, an imino group, an amino group, a substituted amino group, a substituted silyl group, a substituted silyloxy group, a substituted silylthio group, a substituted silylamino group, a mono-valent heterocyclic group, a heterocyclicoxy group, a heterocyclicthio group, an arylalkenyl group, an arylalkynyl group, a carboxyl group or a cyano group. X³ and Ar²¹ are linked to a position adjacent to a hetero ring contained in Ar¹¹, and C(R⁵⁰)(R⁵¹) and Ar¹¹ are linked to a position adjacent to a hetero ring contained in Ar²¹.

In the formula (3), Ar¹¹ and Ar²¹ are the same or mutually different and represent a tri-valent aromatic group. The tri-valent aromatic group means an atomic group remaining after removing three hydrogen atoms on an aromatic ring from an aromatic compound. The aromatic compound may be a carbocyclic compound or a heterocyclic compound. Here, the heterocyclic compound includes organic compounds having a cyclic structure in which elements constituting the ring include not only a carbon atom but also a hetero atom such as oxygen, sulfur, nitrogen, phosphorus, boron and the like contained in the ring.

The atomic group remaining after removing three hydrogen atoms on an aromatic ring from an aromatic carbocyclic compound includes, for example, groups represented by the following formulae, and these may be substituted by a hydrogen atom, a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an imide group, an imino group, an amino group, a substituted amino group, a substituted silyl group, a substituted silyloxy group, a substituted silylthio group, a substituted silylamino group, a mono-valent heterocyclic group, a heterocyclicoxy group, a heterocyclicthio group, an arylalkenyl group, an arylalkynyl group, a carboxyl group or a cyano group.

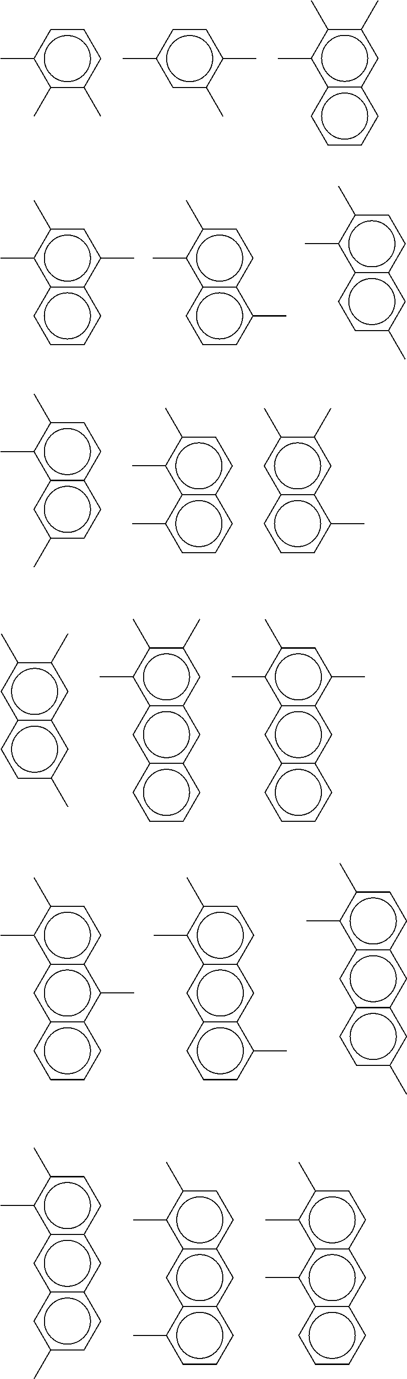

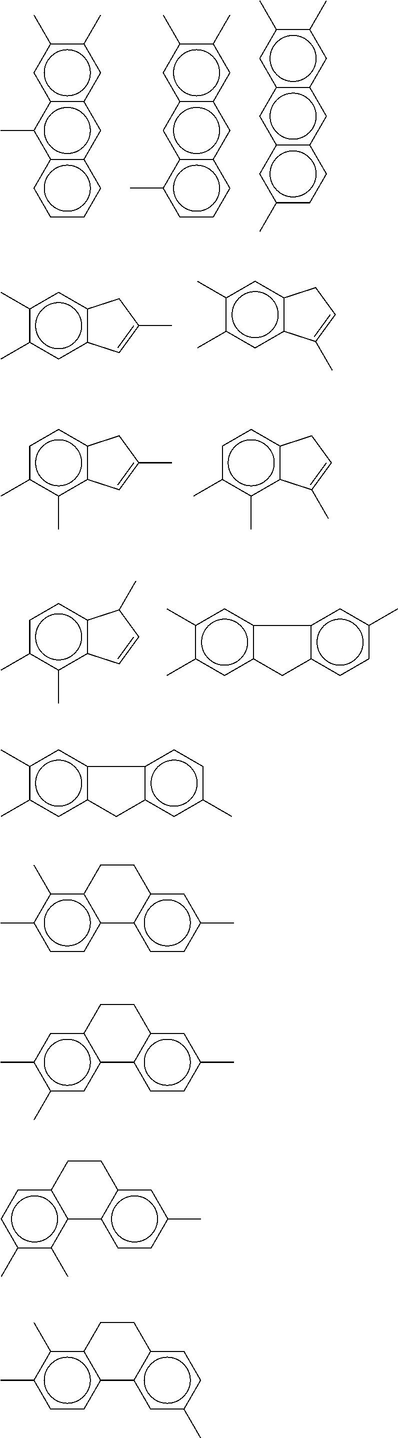

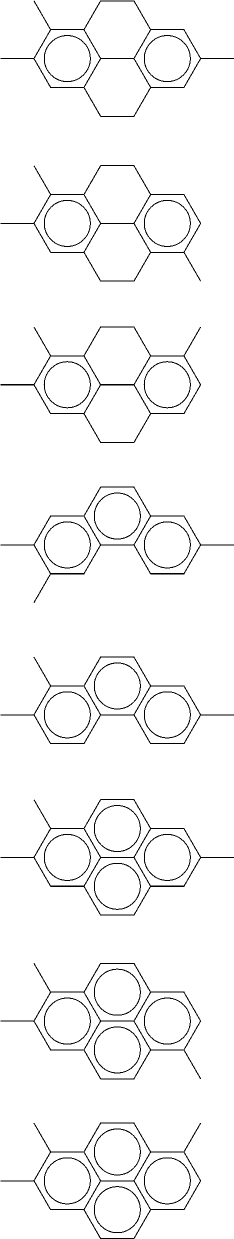

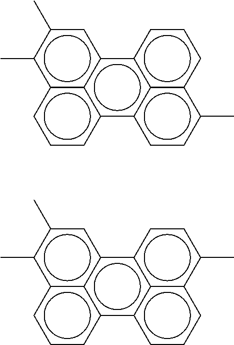

The tri-valent heterocyclic group as the atomic group remaining after removing three hydrogen atoms on an aromatic ring from an aromatic heterocyclic compound includes, for example, groups represented by the following formulae, and these may be substituted by a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an imide group, an imino group, an amino group, a substituted amino group, a substituted silyl group, a substituted silyloxy group, a substituted silylthio group, a substituted silylamino group, a mono-valent heterocyclic group, a heterocyclicoxy group, a heterocyclicthio group, an arylalkenyl group, an arylalkynyl group, a carboxyl group or a cyano group.

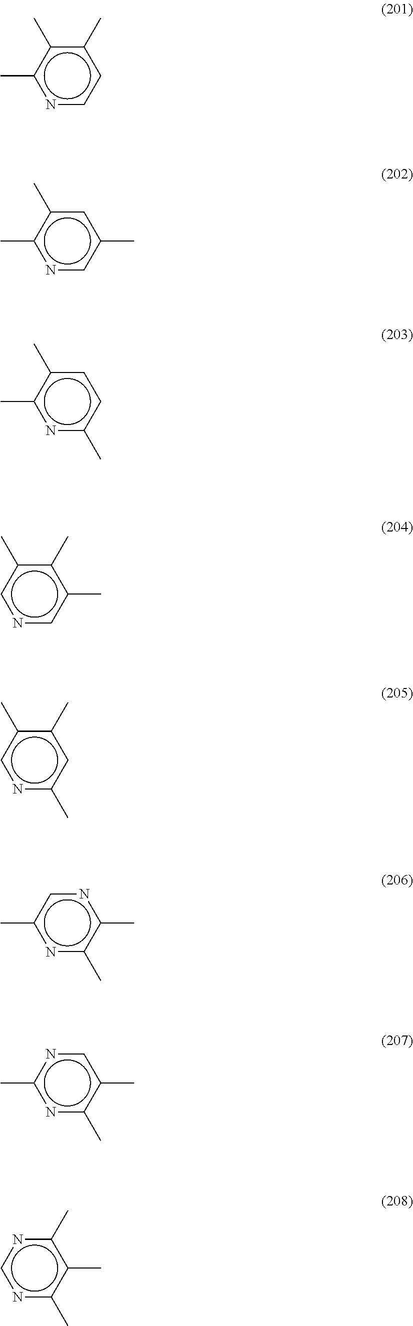

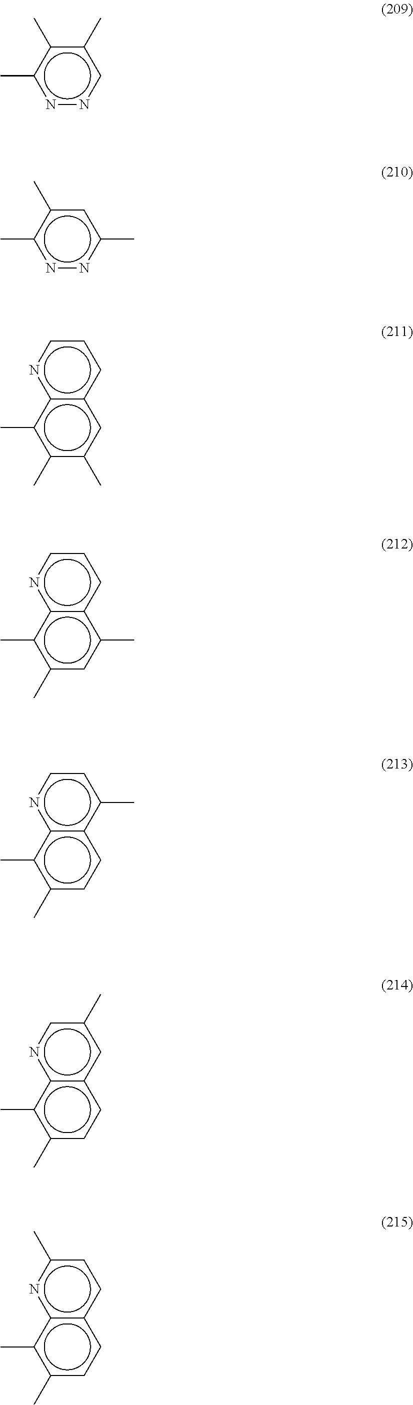

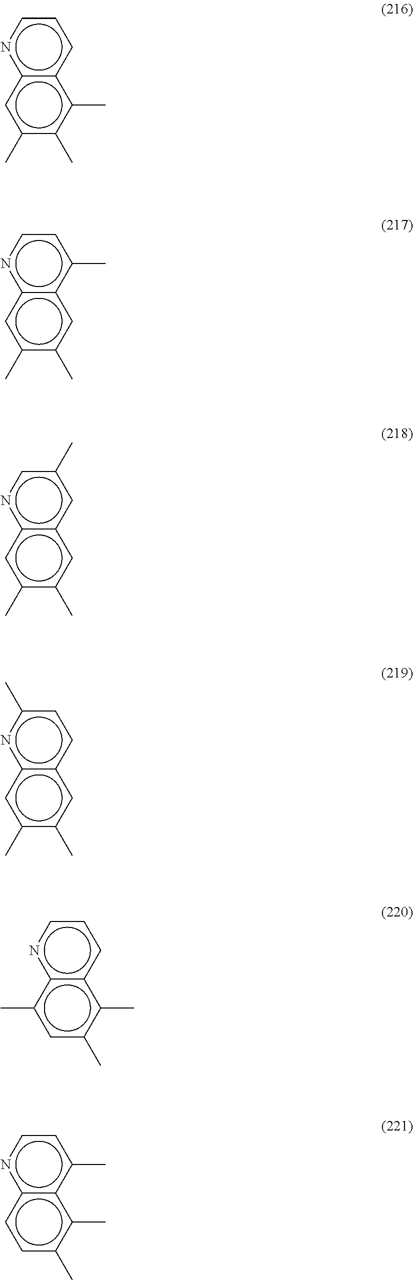

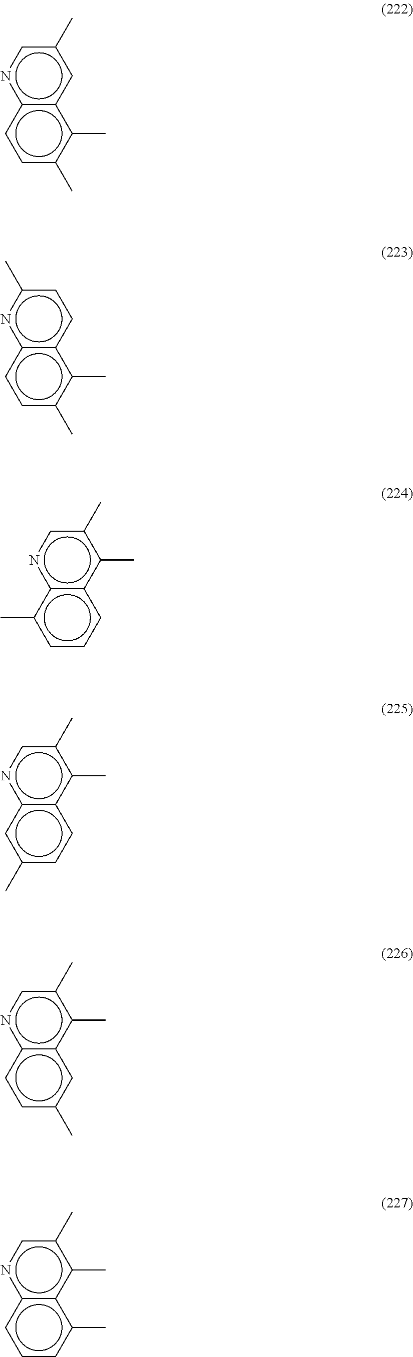

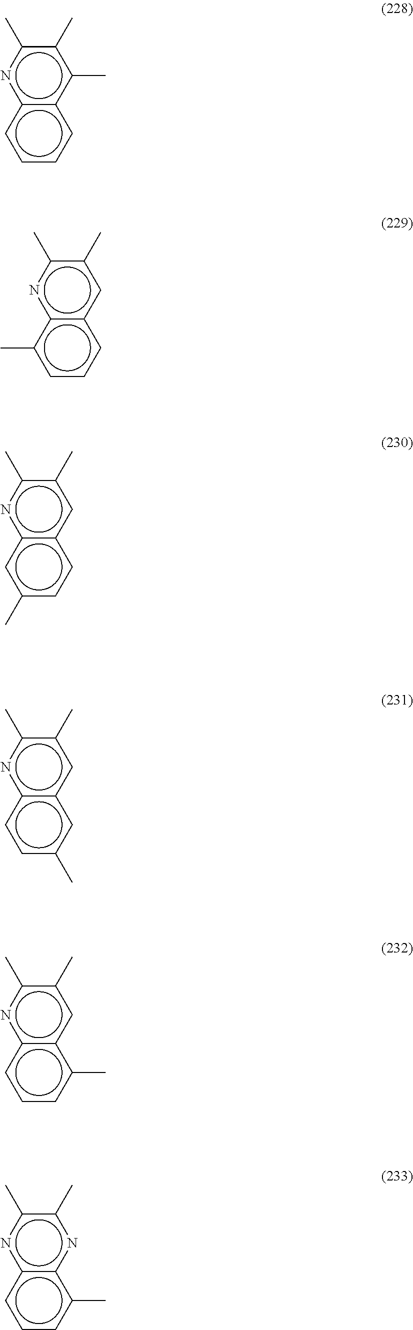

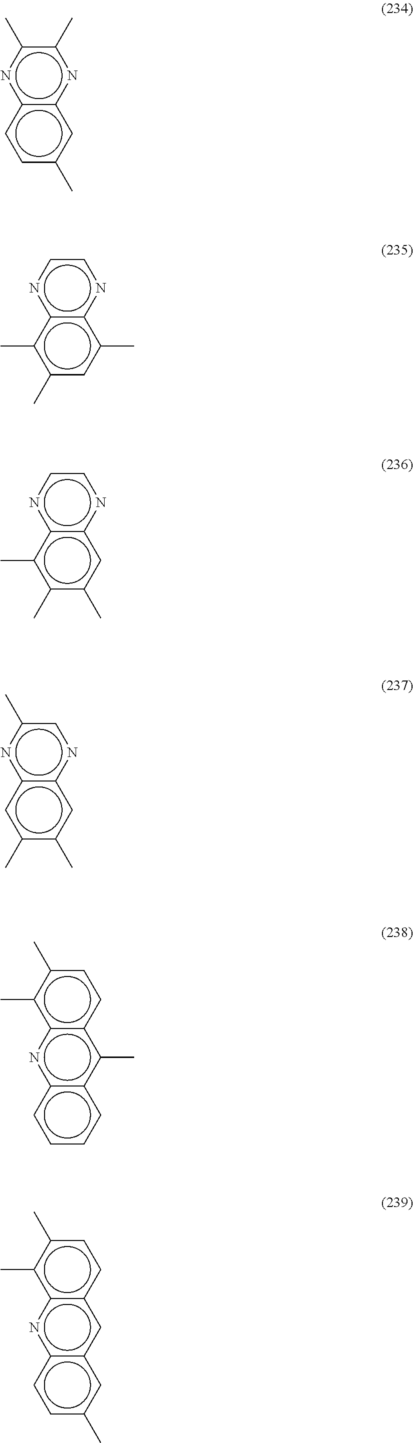

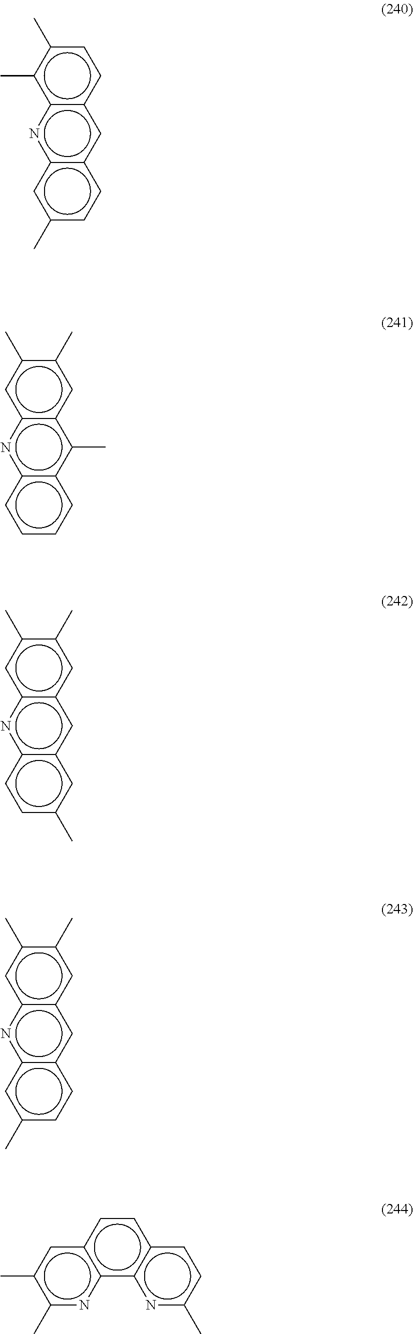

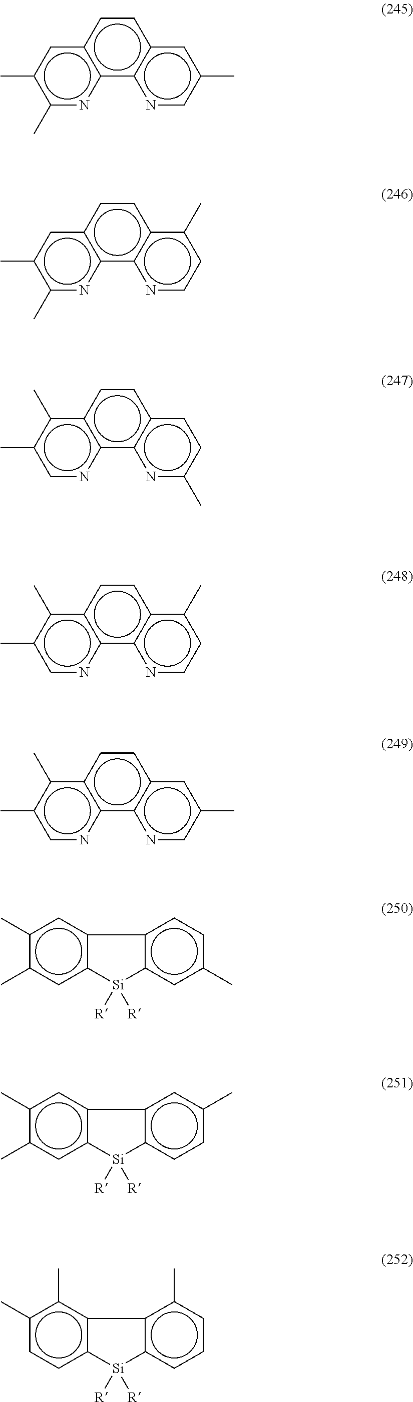

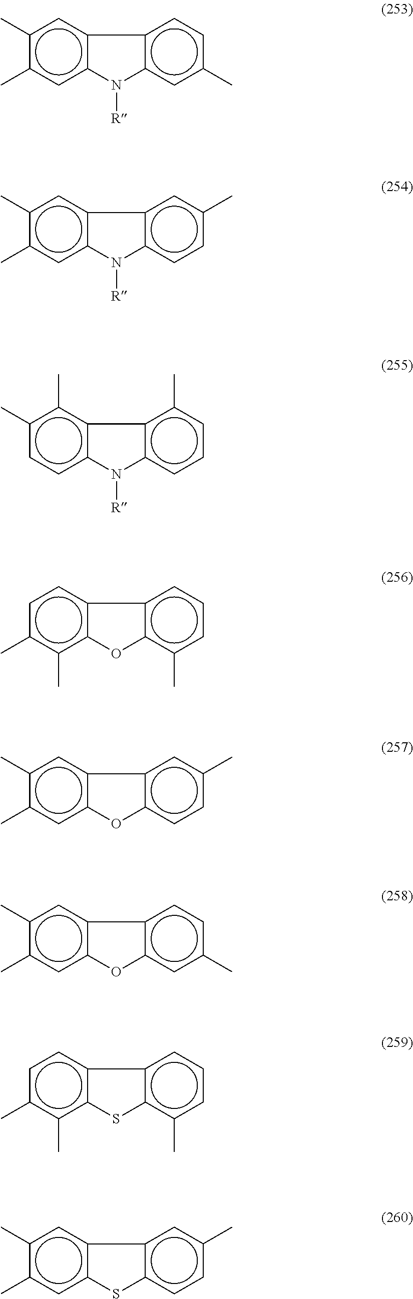

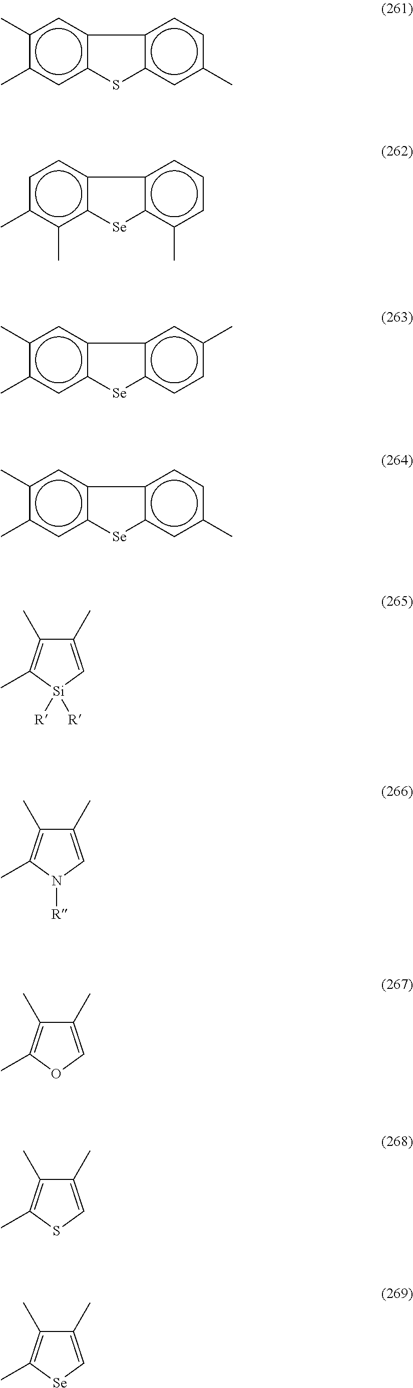

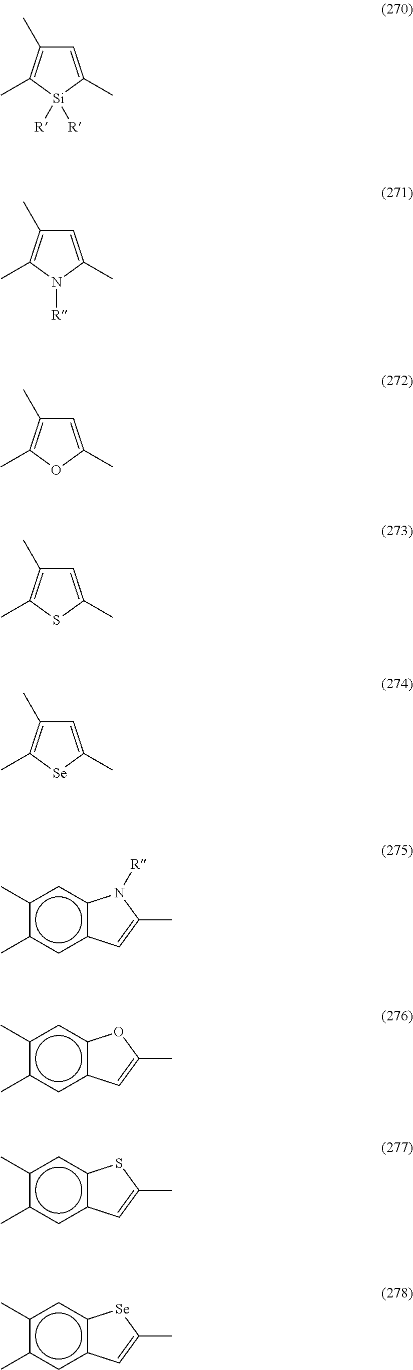

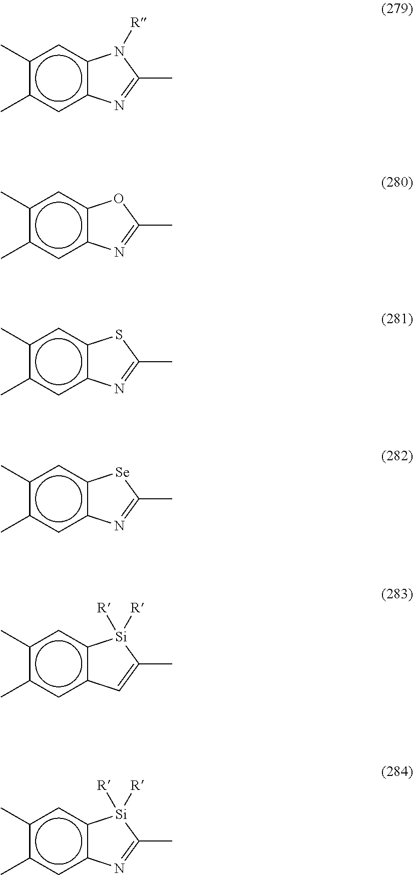

In the formulae (201) to (284), R's are the same or mutually different and represent a hydrogen atom, a halogen atom, an alkyl group, an alkoxy group, an alkylthio group, an aryl group, an aryloxy group, an arylthio group, an arylalkyl group, an arylalkoxy group, an arylalkylthio group, a substituted amino group, an acyloxy group, an amide group, an arylalkenyl group, an arylalkynyl group, a mono-valent heterocyclic group or a cyano group.

R″s are the same or mutually different and represent a hydrogen atom, an alkyl group, an aryl group, an arylalkyl group, a substituted silyl group, an acyl group or a mono-valent heterocyclic group.

It is preferable that both Ar¹¹ and Ar²¹ are a tri-valent heterocyclic group, it is preferable that at least one them is a group obtained by removing three hydrogen atoms from a thiophene ring, and it is more preferable that both of them are a group obtained by removing three hydrogen atoms from a thiophene ring.

In the formulae (201) to (284), the tri-valent heterocyclic group is preferably a heterocyclic group containing a sulfur atom, more preferably a group represented by the formula (268) or the formula (273), further preferably a group represented by the formula (273).

R⁵⁰ and R⁵¹ are preferably the same or mutually different and represent an alkyl group having 6 or more carbon atoms, an alkoxy group having 6 or more carbon atoms, an alkylthio group having 6 or more carbon atoms, an aryl group having 6 or more carbon atoms, an aryloxy group having 6 or more carbon atoms, an arylthio group having 6 or more carbon atoms, an arylalkyl group having 7 or more carbon atoms, an arylalkoxy group having 7 or more carbon atoms, an arylalkylthio group having 7 or more carbon atoms, an acyl group having 6 or more carbon atoms or an acyloxy group having 6 or more carbon atoms, further preferably an alkyl group having 6 or more carbon atoms, an alkoxy group having 6 or more carbon atoms, an aryl group having 6 or more carbon atoms or an aryloxy group having 6 or more carbon atoms, particularly preferably an alkyl group having 6 or more carbon atoms.

As the polymer compound having a structural unit represented by the formula (1), a polymer compounds A is exemplified.

The polymer compound A has the following repeating unit. In the formula, n represents the number of the repeating unit.

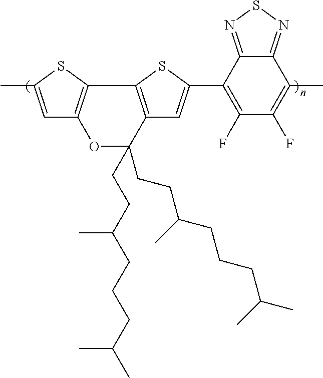

In the present invention, one polymer compound or two or more polymer compounds may be contained in an active layer. Whether the polymer compound acts as an electron donating compound or as an electron acceptive compound is determined relatively according to the energy level of the compound.

It is preferable that the polymer compound contained in an organic photoelectric conversion device material of the present invention has a long light absorption terminal wavelength, from the standpoint of enhancement of photoelectric conversion efficiency. The light absorption terminal wavelength is preferably 700 nm or more, more preferably 800 nm or more, particularly preferably 900 nm or more.

In the present invention, the light absorption terminal wavelength denotes a value measured by the following method.

For measurement, use is made of a spectrophotometer functioning in a region of the wavelength of ultraviolet, visible and near-infrared (for example, ultraviolet visible near-infrared spectrophotometer JASCO-V670, manufactured by JASCO Corporation). Since the measurable wavelength range is from 200 to 1500 nm in the case of use of JASCO-V670, measurement is performed in this wavelength range. First, the absorption spectrum of a substrate used for measurement is measured. As the substrate, use is made of a quartz substrate, a glass substrate and the like. Then, on the substrate, a film containing a polymer compound is formed from a solution containing the polymer compound or a molten material containing the polymer compound. In film formation from a solution, drying is performed after the film formation. Thereafter, the absorption spectrum of a laminate of the film and the substrate is measured. The difference between the absorption spectrum of a laminate of the film and the substrate and the absorption spectrum of the substrate is regarded as the absorption spectrum of the film.

In the absorption spectrum of the film, the ordinate axis represents the absorbance of a polymer compound and the abscissa axis represents wavelength. It is desirable to regulate the thickness of a film so that the absorbance of the largest absorption peak is about 0.5 to 2. The absorbance of an absorption peak of the longest wavelength among absorption peaks is regarded as 100%, and an intersection point of a straight line parallel to the abscissa axis (wavelength axis) containing the 50% absorbance thereof and the absorption peak, situated at the longer side than the peak wavelength of the absorption peak, is defined as a first point. An intersection point of a straight line parallel to the wavelength axis containing the 25% absorbance thereof and the absorption peak, situated at the longer side than the peak wavelength of the absorption peak, is defined as a second point. An intersection point of the baseline and a straight line connecting the first point and the second point is defined as the light absorption terminal wavelength. With respect to the baseline, the absorbance of an absorption peak of the longest wavelength is regarded as 100%, and the wavelength of an intersection point of a straight line parallel to the wavelength axis containing the 10% absorbance thereof and the absorption peak, situated at the longer side than the peak wavelength of the absorption peak, is regarded as the basis, and a straight line connecting a third point on the absorption spectrum having wavelength longer by 100 nm than the basis wavelength and a fourth point on the absorption spectrum having wavelength longer by 150 nm than the basis wavelength is defined as the base line.

The organic photoelectric conversion device material according to the present invention contains a solvent. As the solvent, organic solvents are usually used. Examples of the organic solvent include unsaturated hydrocarbon solvents such as toluene, xylene, mesitylene, tetralin, decalin, bicyclohexyl, n-butylbenzene, sec-butylbenzene, tert-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, and ether solvents such as tetrahydrofuran, tetrahydropyran and the like. Of these solvents, halogenated unsaturated hydrocarbon solvents are preferable, dichlorobenzenes are more preferable, orthodichlorobenzene is further preferable.

The amount of a polymer compound containing in the organic photoelectric conversion device material is not particularly restricted, and the optimum range can be appropriately selected, and it is usually 0.1% by weight or more and 10% by weight or less, preferably 0.3% by weight or more and 5% by weight or less, more preferably 0.5% by weight or more and 3% by weight or less, with respect to the weight of the organic photoelectric conversion device material.

The organic photoelectric conversion device material may contain other materials in addition to a polymer compound and a solvent. When the polymer compound is an electron donating compound, the other material includes an electron acceptive compound. When the polymer compound is an electron acceptive compound, the other material includes an electron donating compound.

When the organic photoelectric conversion device material contains an electron acceptive compound and a polymer compound as an electron donating compound, the sum of the amount of the electron donating compound and the amount of the electron acceptive compound in the organic photoelectric conversion device material is usually 0.2% by weight or more and 20% by weight or less, preferably 0.5% by weight or more and 10% by weight or less, more preferably 1% by weight or more and 5% by weight or less, with respect to the weight of the organic photoelectric conversion device material. The compounding ratio of the electron donating compound to the electron acceptive compound is usually 1 to 20:20 to 1, preferably 1 to 10:10 to 1, further preferably 1 to 5:5 to 1. When a solution of the electron donating compound and a solution of the electron acceptive compound are prepared separately, the electron donating compound or the electron acceptive compound is added in an amount of usually 0.4% by weight or more, preferably 0.6% by weight or more, more preferably 2% by weight or more.

The electron donating compound includes, for example, pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having an aromatic amine residue in the side chain or the main chain, polyaniline and derivatives thereof, polythiophene and derivatives thereof, polypyrrole and derivatives thereof, polyphenylenevinylene and derivatives thereof, polythienylenevinylene and derivatives thereof.

The electron acceptive compound includes, for example, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, phenanthroline derivatives such as bathocuproine and the like, metal oxides such as titanium oxide and the like, carbon nanotubes and the like. The electron acceptive compound includes, preferably, titanium oxide, carbon nanotubes, fullerenes and fullerene derivatives, particularly preferably, fullerenes and fullerene derivatives. Fullerene derivatives are compounds obtained by at least partially modifying fullerenes.

Examples of fullerenes include C60 fullerene, C70 fullerene, C76 fullerene, C78 fullerene, C84 fullerene and the like.

Examples of fullerene derivatives include a compound represented by the formula (6), a compound represented by the formula (7), a compound represented by the formula (8) and a compound represented by the formula (9).

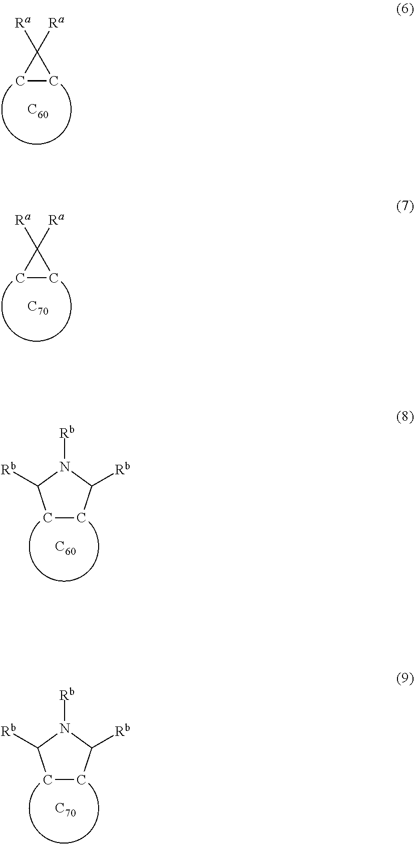

In the formulae (6) to (9), R^{a} represents an alkyl group, an aryl group, a heteroaryl group or a group having an ester structure. A plurality of R^{a}s may be the same or mutually different. R^{b} represents an alkyl group or an aryl group. A plurality of R^{b}s may be the same or mutually different.

The group having an ester structure represented by R^{a} includes, for example, a group represented by the formula (10).

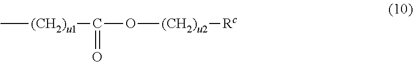

(wherein, u1 represents an integer of 1 to 6, u2 represents an integer of 0 to 6, and R^{c} represents an alkyl group, an aryl group or a heteroaryl group.).

In the present invention, specific examples of the heteroaryl group include a thienyl group, a pyrrolyl group, a furyl group, a pyridyl group, a quinolyl group and an isoquinolyl group.

Examples of fullerenes and fullerene derivatives include C₆₀, C₇₀, C₇₆, C₇₈, C₈₄ and derivatives thereof. Derivatives of C₆₀ fullerene and derivatives of C₇₀ fullerene include the following compounds.

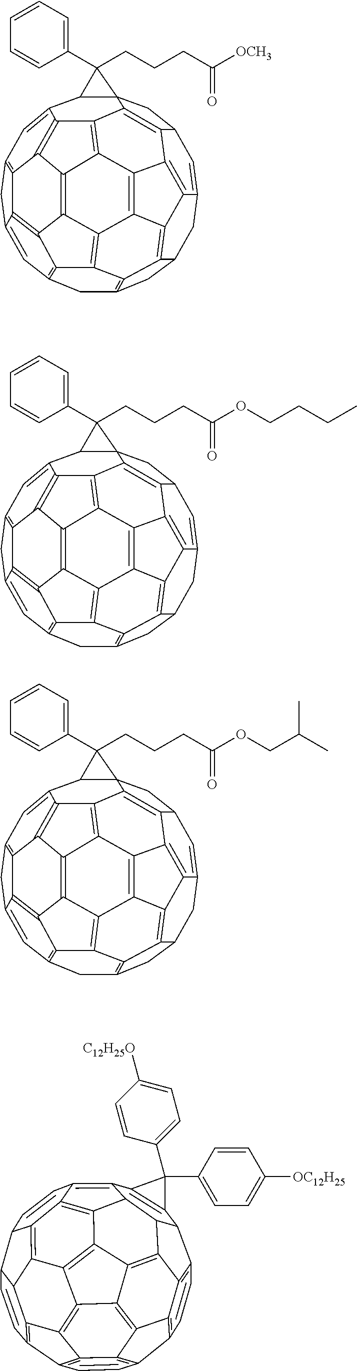

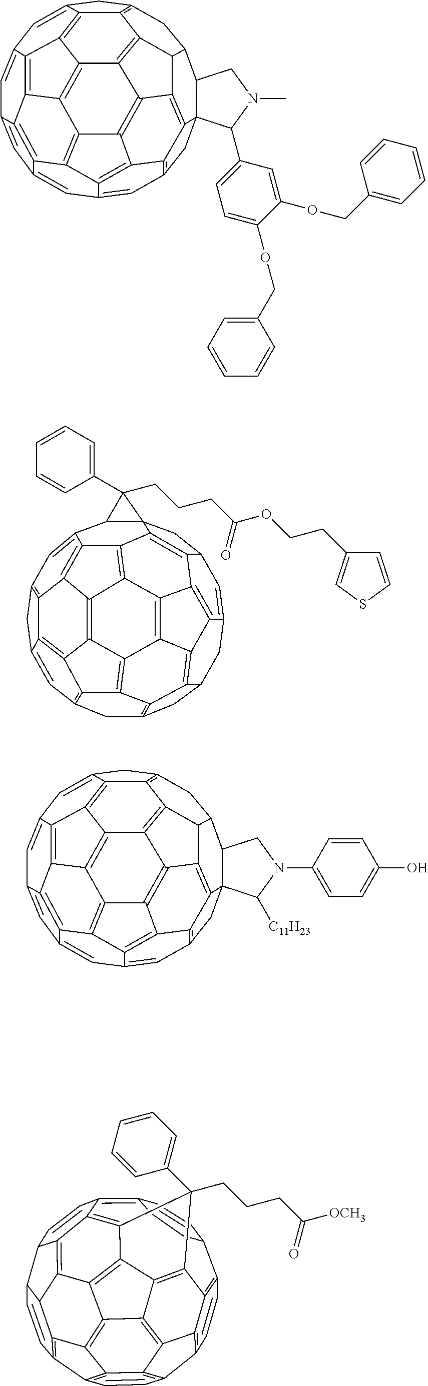

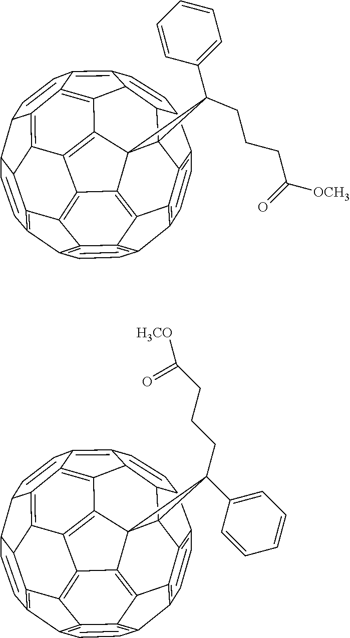 [SMILES: COC(=O)CCCC1(c2ccccc2)C23c4c5c6c7c8c4C4C9=C8C=CC7C7C=CC8=C(c%10c-5c2c2c5c(ccc8c%105)-c5ccc8c(c5-2)C13C4C8C=C9)C67 ; COC(=O)CCCC1(c2ccccc2)C23c4c5c6c7c8c4C4C9=C8C=CC7C7C=CC8=C(c%10c-5c2c2c5c(ccc8c%105)-c5ccc8c(c5-2)C13C4C8C=C9)C67]

Examples of fullerene derivatives include [5,6]-phenyl C61 butyric acid methyl ester ([5,6]-PCBM), [6,6]-phenyl C61 butyric acid methyl ester (C60PCBM, [6,6]-Phenyl C61 butyric acid methyl ester), [6,6]-phenyl C71 butyric acid methyl ester (C70PCBM, [6,6]-Phenyl C71 butyric acid methyl ester), [6,6]-phenyl C85 butyric acid methyl ester (C84PCBM, [6,6]-Phenyl C85 butyric acid methyl ester), [6,6]-thienyl C61 butyric acid methyl ester ([6,6]-Thienyl C61 butyric acid methyl ester) and the like.

The organic photoelectric conversion device according to the present invention will be illustrated using drawings.

The reduction scale of each member in drawings in the following explanation is different from an actual scale in some cases. Though members such as lead wires of an electrode and the like are present in an organic photoelectric conversion device, description and graphic representation thereof are omitted since they are not directly correlated as explanation of the present invention. In the following explanation, one of thickness directions of a substrate is called “upward” or “upper” and the other of thickness directions of a substrate is called “downward” or “lower” in some cases. This vertical relation is set for the sake of explanation convenience, and not necessarily applied to a step in which an organic photoelectric conversion device is actually produced and use conditions thereof.

The basic constitution of the organic photoelectric conversion device according to the present invention is a constitution having a pair of electrodes and an active layer. At least one of the pair of electrodes is usually transparent or semi-transparent. In the organic photoelectric conversion device, the anode is usually a transparent or semi-transparent electrode. The organic photoelectric conversion device may have an opaque electrode. When the organic photoelectric conversion device has an opaque electrode, the opaque electrode is usually a cathode. The location of an active layer in the organic photoelectric conversion device is between a pair of electrodes. One active layer may be present, and also, several active layers may be present. A layer other than the active layer may be disposed between a pair of electrodes, and this layer is referred to as an intermediate layer in some cases in the present specification.

The active layer contains at least one organic compound. The at least one organic compound is a polymer compound. As the organic compound, electron donating compounds (p-type semiconductor) and electron acceptive compounds (n-type semiconductor) are exemplified. The active layer may be a single layer or a laminate having a plurality of layers laminated. Exemplified as the form of an active layer are a so-called pn hetero-junction type form in which a layer formed of an electron donating compound (electron donating layer) and a layer formed of an electron acceptive compound (electron accepting layer) are laminated, and a bulk hetero-junction type form in which an electron donating compound and an electron acceptive compound are mixed to form a bulk hetero-junction structure. The active layer in the present invention may take any form.

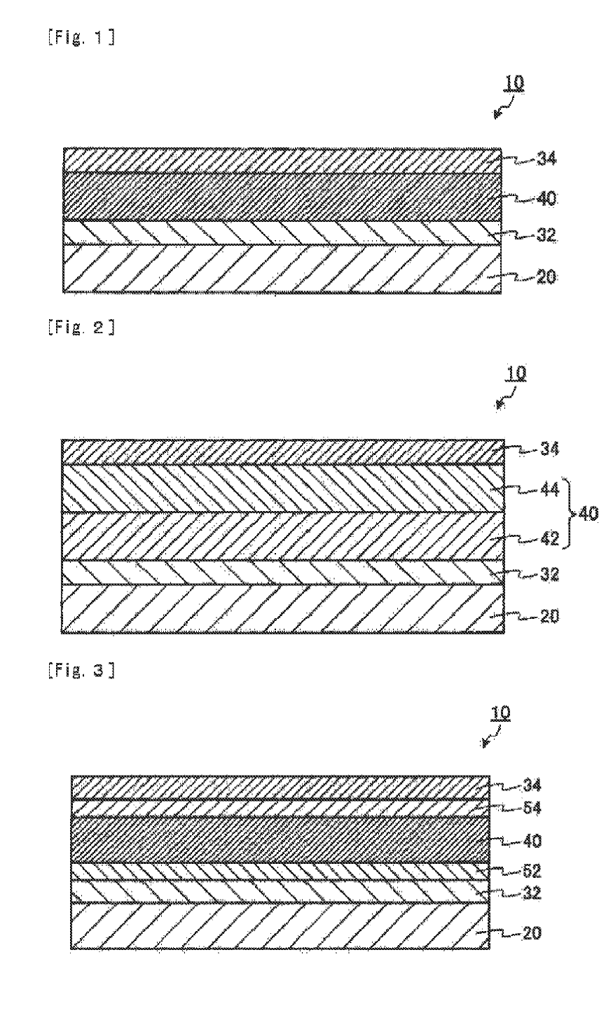

Examples of the layer constitution of an organic photoelectric conversion device will be illustrated referring to FIGS. 1 to 3. FIGS. 1 to 3 are a view showing an example of the layer constitution of an organic photoelectric conversion device. Hereinafter, FIG. 1 will be illustrated, then, only points different from FIG. 1 will be illustrated in FIG. 2, and only points different from FIG. 1 and FIG. 2 will be illustrated in FIG. 3.

In the example of FIG. 1, a laminate having an active layer 40 sandwiched between a first electrode 32 and a second electrode 34 is mounted on a substrate 20, constituting an organic photoelectric conversion device 10. When letting light in from the substrate 20 side, the substrate 20 is transparent or semi-transparent.

At least one of the first electrode 32 and the second electrode 34 is transparent or semi-transparent. When letting light in from the substrate 20 side, the first electrode 32 is transparent or semi-transparent.

Which of the first electrode 32 and the second electrode 32 is an anode or a cathode is not particularly restricted. For example, if a vapor-deposition method is used for film formation of a cathode (for example, aluminum and the like) in the case of producing an organic photoelectric conversion device 10 by sequential lamination from the substrate 20 side, vapor-deposition is preferably carried out in a more later step in some cases. Thus, in this example, it is preferable that the first electrode 32 is an anode and the second electrode 34 is a cathode. In this example, it is sometimes difficult to make an aluminum electrode transparent or semi-transparent depending on setting of the thickness. Therefore, for letting light in from the substrate 20 side, it is preferable that the substrate 20 and the first electrode 32 are made transparent or semi-transparent.

In the example of FIG. 2, the active layer 40 is constituted of two layers, a first active layer 42 and a second active layer 44, and is a pn-hetero-junction type active layer. One of the first active layer 42 and the second active layer 44 is an electron accepting layer, and the other layer is an electron donating layer.

In the example of FIG. 3, a first intermediate layer 52 and a second intermediate layer 54 are provided. The first intermediate layer 52 is situated between the active layer 40 and the first electrode 32, and the second intermediate layer 54 is situated between the active layer 40 and the second electrode 34, respectively. It is also permissible that only one of the first intermediate layer 52 and the second intermediate layer 54 is provided. In FIG. 3, each intermediate layer is depicted as a single layer, however, each intermediate layer may be constituted of several layers.

The intermediate layer may have various functions. If the first electrode 32 hypothesized as an anode, the first intermediate layer 52 can be, for example, a hole transporting layer, an electron blocking layer, a hole injection layer or a layer having another function. In this case, the second electrode 34 is a cathode, and the second intermediate layer 54 can be, for example, an electron transporting layer, an electron blocking layer or a layer having another function. In contrast, if the first electrode 32 is a cathode and the second electrode 34 is an anode, then, also intermediate layers correspondingly transpose respective positions.

The electron donating compound and the electron acceptive compound contained in an active layer are not particularly restricted, and can be determined relatively according to the energy level of these compounds.

An electron donating compound may be used singly in an active layer, or two or more electron donating compounds may be used in combination in an active layer. An electron acceptive compound may be used singly in an active layer, or two or more electron acceptive compounds may be used in combination in an active layer.

It is preferable that the organic photoelectric conversion device material of the present invention is used for formation of an active layer.

When the active layer contains the above-described polymer compound and a fullerene derivative as an electron acceptive compound, the amount of the fullerene derivative in the active layer is preferably 10 to 1000 parts by weight, more preferably 20 to 500 parts by weight with respect to 100 parts by weight of the above-described polymer compound.

In the case of producing an organic photoelectric conversion device having a bulk hetero-junction type active layer, for example, a solution containing the above-described polymer compound and an electron donating compound or an electron acceptive compound is subjected to two or more ultrasonic wave treatments with different frequencies, then, the solution after the treatment is coated on an electrode and the solvent is volatilized, thus, an active layer can be formed.

In contrast, in the case of producing an organic photoelectric conversion device having a pn hetero-junction type active layer, for example, the organic photoelectric conversion device material of the present invention and a solution containing an electron acceptive compound are subjected to two or more ultrasonic wave treatments with different frequencies, then, the organic photoelectric conversion device material after the treatment is coated on an electrode and the solvent is volatilized to form an electron donating layer. Subsequently, the solution containing an electron acceptive compound after the same treatment is coated on an electron donating layer and the solvent is volatilized to form an electron accepting layer. Thus, an active layer of two layer constitution can be formed. The order of formation of an electron donating layer and an electron accepting layer may be reversed.

The thickness of the active layer is usually 1 nm to 100 μm, preferably 2 nm to 1000 nm, more preferably 5 nm to 500 nm, further more preferably 20 nm to 200 nm.

The substrate may advantageously be one which shows no chemical change in forming an electrode and forming a layer of an organic substance. The material of the substrate includes, for example, glass, plastics, polymer films, silicon and the like. In the case of an opaque substrate, it is preferable that the opposite electrode (that is, an electrode far from the substrate, among a pair of electrodes) is transparent or semi-transparent.

As the electrode material constituting the transparent or semi-transparent electrode, an electrically conductive metal oxide film, a semi-transparent metal film and the like are exemplified. Specifically, use is made of a film fabricated by using an electrically conductive material such as indium oxide, zinc oxide, tin oxide, and composites thereof: indium.tin.oxide (ITO), indium.zinc.oxide (IZO), NESA and the like and a film made of a metal such as gold, platinum, silver, copper and the like, and preferable is a film fabricated by using an electrically conductive material composed of ITO, indium.zinc.oxide, tin oxide and the like. As the method of making an electrode, a vacuum vapor deposition method, a sputtering method, an ion plating method, a plating method and the like are exemplified. Further, an organic transparent electrically conductive film made of polyaniline and derivatives thereof, polythiophene and derivatives thereof and the like may be used as the electrode material.

The electrode becoming paired with the transparent or semi-transparent electrode may be transparent or semi-transparent, however, may be neither transparent nor semi-transparent. As the electrode material constituting the electrode, metals, electrically conductive polymers and the like can be used. Specific examples of the electrode material include metals such as lithium, sodium, potassium, rubidium, cesium, magnesium, calcium, strontium, barium, aluminum, scandium, vanadium, zinc, yttrium, indium, cerium, samarium, europium, terbium, ytterbium and the like; alloys composed of two or more metals among the above-described metals; alloys composed of at least one of the above-described metals and at least one selected from the group consisting of gold, silver, platinum, copper, manganese, titanium, cobalt, nickel, tungsten and tin; graphite, graphite intercalation compounds; polyaniline and derivatives thereof, polythiophene and derivatives thereof. The alloy includes a magnesium-silver alloy, a magnesium-indium alloy, a magnesium-aluminum alloy, an indium-silver alloy, a lithium-aluminum alloy, a lithium-magnesium alloy, a lithium-indium alloy, a calcium-aluminum alloy and the like.

As the material of an intermediate layer, exemplified are halides or oxides of alkali metals or alkaline earth metals such as lithium fluoride (LiF) and the like, fine particles of inorganic semiconductors such as titanium oxide and the like, metal alkoxides and PEDOT (poly(3,4)ethylenedioxythiophene). As the intermediate layer on the anode side, preferable is a layer composed of PEDOT, among these materials. As the intermediate layer on the cathode side, preferable are a layer composed of a halide of an alkali metal and a film layer of titania formed from titanium isopropoxide, more preferable are a layer composed of lithium fluoride (LiF) and a film layer of titania formed from titanium isopropoxide.

The organic photoelectric conversion device produced according to the present invention is irradiated with a light such as sunlight or the like through a transparent or semi-transparent electrode, thereby generating photovoltaic power between electrodes, thus, it can be operated as an organic film solar battery.

A plurality of organic film solar batteries can also be integrated and used as an organic film solar battery module.

By irradiating with a light through a transparent or semi-transparent electrode under condition of application of voltage between electrodes or under condition of no application, photocurrent flows, thus, it can be operated as an organic optical sensor. A plurality of organic optical sensors can also be integrated and used as an organic image sensor.

The organic film solar battery can have a module structure which is basically the same as that of a conventional solar battery module. A solar battery module has generally a structure in which a cell is constituted on a supporting substrate such as a metal, ceramic and the like, the upper side thereof is covered with a filling resin, protective glass and the like and a light is introduced from the opposite side of the supporting substrate, however, it is also possible to provide a structure in which a transparent material such as reinforced glass and the like is used for the supporting substrate, a cell is constituted thereon and a light is introduced from the supporting substrate side. Specifically, module structures called super straight type, sub straight type or potting type, substrate-integrated module structures used in amorphous silicon solar batteries, and the like, are known. For the organic film solar battery of the present invention, these module structures can be appropriately selected depending on the use object, the use place and environments.

A typical module of super straight type or sub straight type has a structure in which cells are disposed at regular interval between supporting substrates of which one side or both sides are transparent and on which a reflection preventing treatment has been performed, adjacent cells are mutually connected by a metal lead or flexible wiring and the like, a power collecting electrode is placed on an outer edge part and generated powder is harvested outside. Between the substrate and the cell, various kinds of plastic materials such as ethylene vinyl acetate (EVA) and the like may be used in the form of a film or filling resin depending on the object, for protection of the cell and for improvement in power collecting efficiency. In the case of use at places requiring no covering of the surface with a hard material such as a place receiving little impact from outside, it is possible that the surface protective layer is constituted of a transparent plastic film, or the above-described filling resin is hardened to impart a protective function, and one supporting substrate is omitted. The circumference of the supporting substrate is fixed in the form of sandwich by a metal frame for tight seal of the inside and for securement of rigidity of the module, and a space between the supporting substrate and the frame is sealed tightly with a sealant. If a flexible material is used as the cell itself, or as the supporting substrate, the filling material and the sealant, a solar battery can be constituted also on a curved surface.

In the case of a solar battery using a flexible support such as a polymer film and the like, a battery body can be fabricated by forming cells sequentially while feeding a support in the form of a roll, cutting into a desired size, then, sealing a peripheral part with a flexible moisture-proof material. Also, a module structure called “SCAF” described in Solar Energy Materials and Solar Cells, 48, p 383-391 can be adopted. Further, a solar battery using a flexible support can also be adhered and fixed to curved glass and the like and used.

When insoluble components and a dust are present in a solution in film formation, crack is generated on the coated film, and insoluble components and a dust act as a nucleus, thereby causing generation of aggregated particles. By this, electrical and chemical contacts at the junction interface become poor and leak current is generated. Photoelectric conversion efficiency is improved by reducing this.

### EXAMPLES

### Synthesis Example 1

### (Synthesis of Compound 1)

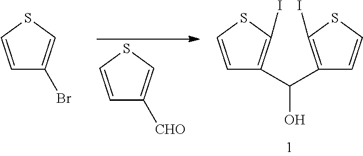 [SMILES: Brc1ccsc1 ; O=Cc1ccsc1 ; OC(c1ccsc1I)c1ccsc1I]

Into a 1000 mL four-necked flask in which a gas in the flask had been purged with argon were charged 13.0 g (80.0 mmol) of 3-bromothiophene and 80 mL of diethyl ether, to prepare a uniform solution. While keeping the solution at −78° C., 31 mL (80.6 mmol) of a 2.6 M hexane solution of n-butyllithium (n-BuLi) was dropped. The mixture was reacted at −78° C. for 2 hours, then, a solution prepared by dissolving 8.96 g (80.0 mmol) of 3-thiophenealdehyde in 20 mL of diethyl ether was dropped. After dropping, the mixture was stirred at −78° C. for 30 minutes, further, stirred at room temperature (25° C.) for 30 minutes. The reaction solution was cooled again to −78° C., and 62 mL (161 mmol) of a 2.6 M hexane solution of n-BuLi was dropped over a period of 15 minutes. After dropping, the reaction solution was stirred at −25° C. for 2 hours, further, stirred at room temperature (25° C.) for 1 hour. Thereafter, the reaction solution was cooled to −25° C., and a solution prepared by dissolving 60 g (236 mmol) of iodine in 1000 mL of diethyl ether was dropped over a period of 30 minutes. After dropping, the mixture was stirred at room temperature (25° C.) for 2 hours, and 50 mL of a 1 N sodium thiosulfate aqueous solution was added to stop the reaction. The reaction product was extracted with diethyl ether, then, dried over magnesium sulfate, and dried to obtain 35 g of a coarse product. The coarse product was purified by re-crystallizing from chloroform, to obtain 28 g of a compound 1.

### (Synthesis of Compound 2)

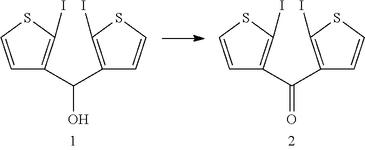 [SMILES: OC(c1ccsc1I)c1ccsc1I ; O=C(c1ccsc1I)c1ccsc1I]

Into a 300 mL four-necked flask were added 10.5 g (23.4 mmol) of bisiodothienyl methanol (compound 1) and 150 mL of methylene chloride, to prepare a uniform solution. To the solution was added 7.50 g (34.8 mmol) of pyridinium chlorochromate and the mixture was stirred at room temperature (25° C.) for 10 hours. The reaction solution was filtrated to remove insoluble materials, then, the filtrate was concentrated to obtain 10.0 g (22.4 mmol) of a compound 2.

### (Synthesis of Compound 3)

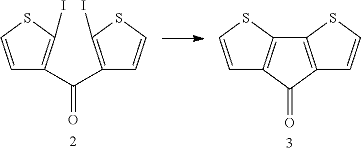 [SMILES: O=C(c1ccsc1I)c1ccsc1I ; O=C1c2ccsc2-c2sccc21]

Into a 300 mL flask in which a gas in the flask had been purged with argon were added 10.0 g (22.4 mmol) of the compound 2, 6.0 g (94.5 mmol) of a copper powder and 120 mL of dehydrated N,N-dimethylformamide (hereinafter, referred to as DMF in some cases), and the mixture was stirred at 120° C. for 4 hours. After the reaction, the flask was cooled down to room temperature (25° C.), and the reaction solution was allowed to pass through a silica gel column to remove insoluble components. Thereafter, 500 mL of water was added, and the reaction product was extracted with chloroform. The oil layer as a chloroform solution was dried over magnesium sulfate, and concentrated to obtain a coarse product. The coarse product was purified by a silica gel column using chloroform as a developing solvent, to obtain 3.26 g of a compound 3. The operations so far were repeated several times.

### (Synthesis of Compound 4)

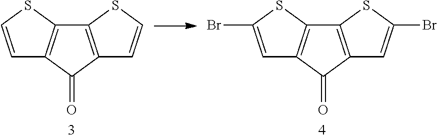 [SMILES: O=C1c2ccsc2-c2sccc21 ; O=C1c2cc(Br)sc2-c2sc(Br)cc21]

Into a flask in which a gas in the flask had been purged with argon were charged 10.0 g (5.20 mmol) of the compound 3 and 100 mL of tetrahydrofuran (hereinafter, referred to as THF in some cases), to prepare a uniform solution. The flask was kept at 0° C., and 2.31 g (1.30 mmol) of N-bromosuccinimide (hereinafter, referred to as NBS in some cases) was added over a period of 15 minutes. Thereafter, the mixture was stirred at 0° C. for 2 hours, the deposited solid was isolated by filtration and washed with a 10 wt % sodium thiosulfate aqueous solution and water. The resultant solid is called a coarse product 4-A. Thereafter, to the filtrate was added 200 mL of a 10 wt % sodium thiosulfate aqueous solution, and the mixture was extracted with chloroform. The organic layer as a chloroform solution was dried over sodium sulfate, and concentrated to obtain a deposited solid. The resultant solid is called a coarse product 4-B. The coarse product 4-A and the coarse product 4-B were combined, and purified by silica gel column chromatography using chloroform as a developing solvent, to obtain 17.3 g of a compound 4. The operations so far were repeated several times.

### (Synthesis of Compound 5)

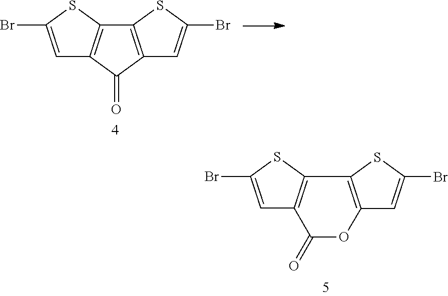 [SMILES: O=C1c2cc(Br)sc2-c2sc(Br)cc21 ; O=c1oc2cc(Br)sc2c2sc(Br)cc12]

Into a 1000 mL four-necked flask having a mechanical stirrer and in which a gas in the flask had been purged with argon were charged 25.0 g (71.4 mmol) of the compound 4, 250 mL of chloroform and 160 mL of trifluoroacetic acid, to prepare a uniform solution. To the solution was added 21.0 g (210 mmol) of sodium perborate mono-hydrate over a period of 35 minutes, and the mixture was stirred at room temperature (25° C.) for 240 minutes. Thereafter, 500 mL of a 5 wt % sodium sulfite aqueous solution was added to the reaction solution to stop the reaction, and sodium hydrogen carbonate was added until the reaction solution showed pH 6. Thereafter, the reaction product was extracted with chloroform, the organic layer as a chloroform solution was allowed to pass through a silica gel column, and the eluate was treated by an evaporator to distill off the solvent. The residue was re-crystallized from methanol, to obtain 7.70 g (21.0 mmol) of a compound 5. The operations so far were repeated several times.

### (Synthesis of Compound 6)

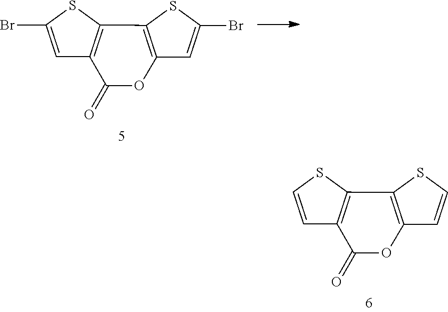 [SMILES: O=c1oc2cc(Br)sc2c2sc(Br)cc12 ; O=c1oc2ccsc2c2sccc12]

Into a 2000 mL flask in which a gas in the flask had been purged with argon were charged 23.1 g (63.1 mmol) of the compound 5 and 1500 mL of THF to prepare a uniform solution. The flask was cooled down to −50° C., and 190 mL of a 1 mol/L THF solution of n-octylmagnesium bromide was dropped over a period of 10 minutes. The reaction solution was stirred at −50° C. for 30 minutes, then, 500 mL of water was added to stop the reaction. The reaction solution was heated up to room temperature (25° C.), 1000 mL of THF was distilled off by an evaporator, and 100 mL of acetic acid was added. The reaction product was extracted with chloroform, and thereafter, the chloroform solution was dried over sodium sulfate, and the solvent was distilled off by an evaporator. The resultant solid was washed with hexane, and dried under reduced pressure to obtain 10.9 g of a compound 6.

### (Synthesis of Compound 7)

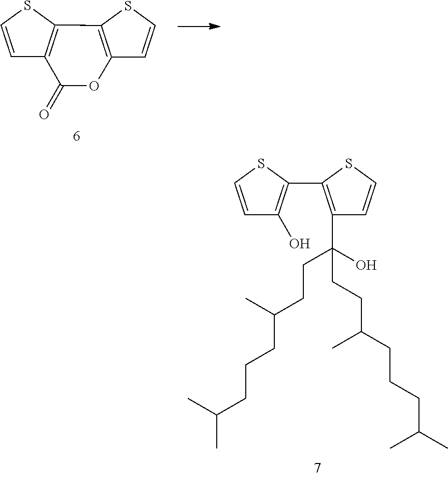 [SMILES: O=c1oc2ccsc2c2sccc12 ; CC(C)CCCC(C)CCC(O)(CCC(C)CCCC(C)C)c1ccsc1-c1sccc1O]

Into a 100 mL four-necked flask in which a gas in the flask had been purged with argon were charged 1.00 g (4.80 mmol) of the compound 6 and 30 ml of dehydrated THF to prepare a uniform solution. While keeping the flask at −20° C., 12.7 mL of a 1 M ether solution of 3,7-dimethyloctylmagnesium bromide was added. Thereafter, the temperature of the reaction solution was raised to −5° C. over a period of 30 minutes, and the solution was stirred for 30 minutes at the same temperature. Thereafter, the temperature of the reaction solution was raised to 0° C. over a period of 10 minutes, and the solution was stirred for 1.5 hours at the same temperature. Thereafter, water was added to the reaction solution to stop the reaction, and the reaction product was extracted with ethyl acetate. The organic layer as an ethyl acetate solution was dried over sodium sulfate, allowed to pass through a silica gel column, and the solvent was distilled off from the eluate, to obtain 1.50 g of a compound 7.

¹H NMR in CDCl₃ (ppm): 8.42 (b, 1H), 7.25 (d, 1H), 7.20 (d, 1H), 6.99 (d, 1H), 6.76 (d, 1H), 2.73 (b, 1H), 1.90 (m, 4H), 1.58-1.02 (b, 20H), 0.92 (s, 6H), 0.88 (s, 12H)

### (Synthesis of Compound 8)

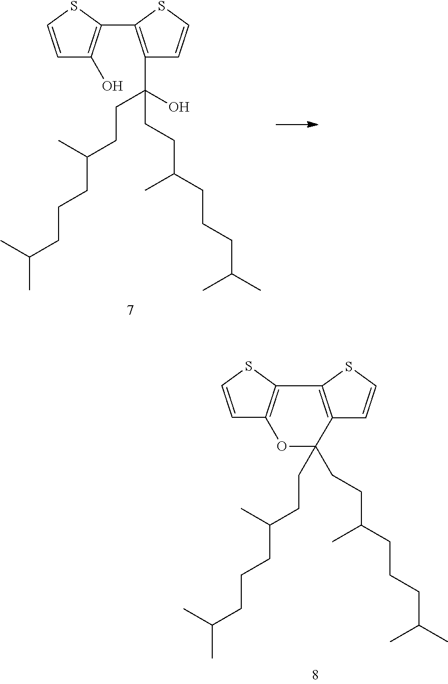 [SMILES: CC(C)CCCC(C)CCC(O)(CCC(C)CCCC(C)C)c1ccsc1-c1sccc1O ; CC(C)CCCC(C)CCC1(CCC(C)CCCC(C)C)Oc2ccsc2-c2sccc21]

Into a 200 mL flask in which a gas in the flask had been purged with argon were charged 1.50 g of the compound 7 and 30 mL of toluene to prepare a uniform solution. To the solution was added 100 mg of sodium p-toluenesulfonate mono-hydrate, and the mixture was stirred at 100° C. for 1.5 hours. The reaction solution was cooled down to room temperature (25° C.), then, 50 mL of water was added, and the reaction product was extracted with toluene. The organic layer as a toluene solution was dried over sodium sulfate, and the solvent was distilled off. The resultant coarse product was purified by a silica gel column using hexane as a developing solvent, to obtain 1.33 g of a compound 8. The operations so far were repeated several times.

¹H NMR in CDCl₃ (ppm): 6.98 (d, 1H), 6.93 (d, 1H), 6.68 (d, 1H), 6.59 (d, 1H), 1.89 (m, 4H), 1.58-1.00 (b, 20H), 0.87 (s, 6H), 0.86 (s, 12H)

### (Synthesis of Compound 9)

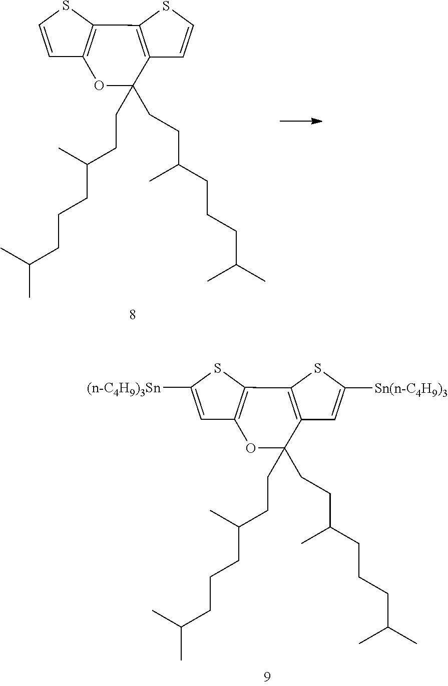

Into a 200 mL flask in which a gas in the flask had been purged with argon were charged 2.16 g (4.55 mmol) of the compound 8 and 100 mL of dehydrated THF to prepare a uniform solution. The solution was kept at −78° C., and 4.37 mL (11.4 mmol) of a 2.6 M hexane solution of n-butyllithium was dropped into the solution over a period of 10 minutes. After dropping, the reaction solution was stirred at −78° C. for 30 minutes, then, stirred at room temperature (25° C.) for 2 hours. Thereafter, the flask was cooled down to −78° C., and 4.07 g (12.5 mmol) of tributyltin chloride was added. After addition, the mixture was stirred at −78° C. for 30 minutes, then, stirred at room temperature (25° C.) for 3 hours. Thereafter, 200 ml of water was added to stop the reaction, and the reaction product was extracted with ethyl acetate. The organic layer as an ethyl acetate solution was dried over sodium sulfate, and the solvent was distilled off by an evaporator. The resultant oily substance was purified by a silica gel column using hexane as a developing solvent, to obtain 3.52 g (3.34 mmol) of a compound 9. As the silica gel in the silica gel column, silica gel which had been previously immersed in hexane containing 5 wt % triethylamine for 5 minutes, then, rinsed with hexane was used.

### Synthesis Example 2

### (Synthesis of Compound 10)

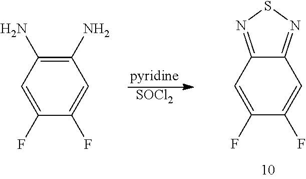

Into a 500 ml flask were charged 10.2 g (70.8 mmol) of 4,5-difluoro-1,2-diaminobenzene (manufactured by Tokyo Chemical Industry Co., Ltd.) and 150 mL of pyridine to prepare a uniform solution. While keeping the flask at 0° C., 16.0 g (134 mmol) of thionyl chloride was dropped into the flask. After dropping, the flask was warmed at 25° C., and the reaction thereof was performed for 6 hours. Thereafter, 250 ml of water was added, and the reaction product was extracted with chloroform. The organic layer as a chloroform solution was dried over sodium sulfate, and concentrated by an evaporator. The deposited solid was re-crystallized from methanol, to obtain 10.5 g (61.0 mmol) of a purified compound 10.

¹H NMR (CDCl₃, ppm): 7.75 (t, 2H)

¹⁹F NMR (CDCl₃, ppm): −128.3 (s, 2F)

### (Synthesis of Compound 11)

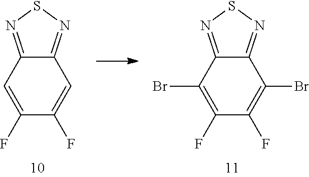 [SMILES: Fc1cc2nsnc2cc1F ; Fc1c(F)c(Br)c2nsnc2c1Br]

Into a 100 mL flask were charged 2.00 g (11.6 mmol) of the compound 10 and 0.20 g (3.58 mmol) of an iron powder, and the flask was heated at 90° C. Into this flask, 31 g (194 mmol) of bromine was dropped over a period of 1 hour. After dropping, the mixture was stirred at 90° C. for 38 hours. Thereafter, the flask was cooled down to room temperature (25° C.), and 100 mL of chloroform was added for dilution. The resultant solution was poured into 300 mL of a 5 wt % sodium sulfite aqueous solution, and the mixture was stirred for 1 hour. The organic layer of the resultant mixed liquid was separated by a separatory funnel, and the aqueous layer was extracted with chloroform three times. The resultant extraction liquid was combined with the organic layer previously separated, and dried over sodium sulfate, and the solvent was distilled off by an evaporator. The resultant yellow solid was dissolved in 90 mL of methanol heated at 55° C., then, the solution was cooled down to 25° C. The deposited crystal was filtrated, and dried under reduced pressure at room temperature (25° C.), to obtain 1.50 g of a compound 11.

¹⁹F NMR (CDCl₃, ppm): −118.9 (s, 2F)

### Synthesis Example 3

### (Synthesis of Polymer Compound A)

Into a 200 mL flask in which a gas in the flask had been purged with argon were charged 500 mg (0.475 mmol) of the compound 9, 141 mg (0.427 mmol) of the compound 11 and 32 ml of toluene to prepare a uniform solution. The resultant toluene solution was bubbled with argon for 30 minutes. Thereafter, to the toluene solution were added 6.52 mg (0.007 mmol) of tris(dibenzylideneacetone)dipalladium and 13.0 mg of tris(2-toluoyl)phosphine, and the mixture was stirred at 100° C. for 6 hours. Thereafter, to the reaction solution was added 500 mg of phenyl bromide, and the mixture was stirred further for 5 hours. Thereafter, the flask was cooled down to 25° C., and the reaction solution was poured into 300 mL of methanol. The deposited polymer was isolated by filtration, the resultant polymer was placed into cylindrical filter paper, and extracted with methanol, acetone and hexane for each 5 hours using a soxhlet extractor. The polymer remaining in the cylindrical filter paper was dissolved in 100 mL of toluene, 2 g of sodium diethyldithiocarbamate and 40 mL of water were added, and the mixture was stirred for 8 hours under reflux. The aqueous layer was removed, then, the organic layer was washed with 50 ml of water twice, 50 mL of a 3 wt % acetic acid aqueous solution twice, 50 mL of water twice, 50 mL of a 5% potassium fluoride aqueous solution twice and 50 mL of water twice in series, and the resultant solution was poured into methanol to cause deposition of a polymer. The polymer was filtrated, then, dried, the resultant polymer was dissolved again in 50 mL of o-dichlorobenzene, and allowed to pass through an alumina/silica gel column. The eluate was poured into methanol to cause deposition of a polymer, and the polymer was filtrated, then, dried to obtain 185 mg of a purified polymer. Hereinafter, this polymer is referred to as a polymer compound A. The polymer compound A had a polystyrene-equivalent weight-average molecular weight of 29000 and a polystyrene-equivalent number-average molecular weight of 14000. The light absorption terminal wavelength of the polymer compound A was 890 nm. The absolute value of the energy of the highest occupied molecular orbital of the polymer compound A was 5.14 eV.

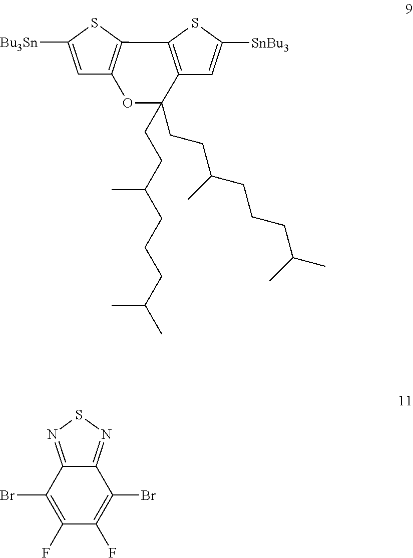

The polymer compound A has the following repeating unit. In the formula, n represents the number of the repeating unit.

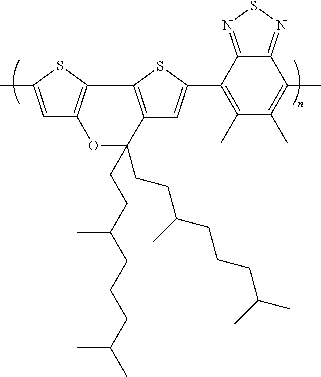

### Example 1

### (Fabrication of Organic Photoelectric Conversion Device)

A glass substrate carrying thereon a patterned ITO film with a thickness of about 150 nm formed by a sputtering method was washed with an organic solvent, an alkali detergent and ultrapure water, and dried. The glass substrate was treated with ultraviolet-ozone (UV-O₃) using an ultraviolet-ozone (UV-O₃) apparatus.

A suspension prepared by dissolving poly(3,4)ethylenedioxythiophene/polystyrenesulfonic acid in water (Bytron P TP AI 4083, manufactured by HC Starck B-Tech Co.) was filtrated through a filter having a pore diameter of 0.5 μm. The suspension after filtration was spin-coated on the ITO side of the substrate, to form a film with a thickness of 70 nm. Then, this was dried on a hot plate at 200° C. for 10 minutes in atmospheric air, to form an organic layer.

Next, 30 ml of orthodichlorobenzene was charged into a glass sample bottle which was then allowed to stand still in a glove box in which the oxygen concentration was 1% or less. The monitor value of an oxygen detector in the glove box showed 0%. A first deoxidizing treatment was performed in which a glass pipette was inserted into orthodichlorobenzene, and nitrogen was allowed to flow in via the pipette for 30 minutes, to cause bubbling with nitrogen in the solvent. Thereafter, [6,6]-phenyl C71-butyric acid methyl ester ([6,6]-Phenyl C71 butyric acid methyl ester) and the polymer compound A were added to orthodichlorobenzene so that the ratio of the weight of the polymer compound A to the weight of [6,6]-phenyl C71-butyric acid methyl ester was 2, to prepare a coating solution. The weight of the polymer compound A was 0.5% by weight with respect to the weight of the coating solution. Thereafter, the coating solution was stirred with heating at 140° C. In stirring with heating, a second deoxidizing treatment was performed in which a glass pipette was inserted into the coating solution, and nitrogen was allowed to flow in via the pipette for 30 minutes, to cause bubbling with nitrogen in the solution. The oxygen concentration at this moment was 3.8 ppm.

A stirrer chip was dropped into the coating solution after the second deoxidizing treatment, and the solution was stirred at a rotation rate of from 300 rpm to 1000 rpm. Stirring was carried out on a hot stirrer with a temperature variable function, and the temperature was set at 140° C. Thereafter, the coating solution was filtrated through a filter having a pore diameter of 0.5 μm, the resultant filtrate was spin-coated on the organic layer, then, dried in a nitrogen atmosphere, to form an active layer.

Titanium(IV) isopropoxide (97%) purchased from SIGMAS ALDRICH was mixed into isopropanol to obtain a concentration of 1 wt %, and the resultant solution was spin-coated on the active layer to form a film with a thickness of 10 nm, subsequently, a film of Al was formed with a thickness of about 70 nm, to form an electrode. Then, a sealing treatment was performed by adhering a glass substrate using an epoxy resin (fast curing Araldite (trade name)) as a sealant, to obtain an organic film solar battery.

### Example 2

### (Fabrication of Organic Photoelectric Conversion Device)

An organic photoelectric conversion device was fabricated in the same manner as in Example 1 excepting that, in stirring the coating solution after the second deoxidizing treatment, a third deoxidizing treatment was performed in which a glass pipette was inserted into the coating solution, and nitrogen was allowed to flow in via the pipette for 30 minutes, to cause bubbling with nitrogen in the solution. The oxygen concentration of the coating solution at this moment was 0.8 ppm.

### Comparative Example 1

### (Fabrication of Organic Photoelectric Conversion Device)

An organic photoelectric conversion device was fabricated in the same manner as in Example 1 excepting that the first deoxidizing treatment and the second deoxidizing treatment were not carried out. The oxygen concentration of the coating solution used at this moment was 25.2 ppm.

### (Evaluation of Photoelectric Conversion Efficiency)

The organic film solar batteries as the organic photoelectric conversion device obtained in Example 1, Example 2 and Comparative Example 1 had a 2 mm×2 mm square shape. These organic film solar batteries were irradiated with a constant light using Solar Simulator (manufactured by BUNKOUKEIKI Co., Ltd., trade name: type CEP-2000, irradiance: 100 mW/cm²), and the generated current and voltage were measured and photoelectric conversion efficiency was calculated. The results are shown in Table 1.

TABLE 1

| | Photoelectric conversion efficiency (%) |
|---|---|
| Example 1 | 5.23% |
| Example 2 | 6.99% |
| Comparative | 2.68% |
| Example 1 | |

### INDUSTRIAL APPLICABILITY

The present invention is useful since an organic photoelectric conversion device excellent in photoelectric conversion efficiency can be produced by the production method of the present invention.

1. A method of producing an organic photoelectric conversion device having a pair of electrodes and an active layer containing a polymer compound disposed between the pair of electrodes, comprising a step of forming the active layer using a solution containing the polymer compound and a deoxidized solvent.

2. The method according to claim 1, wherein the step of forming the active layer is conducted by coating the solution containing the polymer compound and a deoxidized solvent on an electrode.

3. The method according to claim 1, wherein the deoxidizing treatment is a treatment of introducing nitrogen.

4. The method according to claim 1, wherein the oxygen weight concentration in the solution containing the polymer compound and a deoxidized solvent is 25 ppm or less.

5. The method according to claim 1, wherein the oxygen weight concentration in the solution containing the polymer compound and a deoxidized solvent is 10 ppm or less.

6. The method according to claim 1, wherein the polymer compound is a polymer compound containing a structural unit represented by the formula (1): 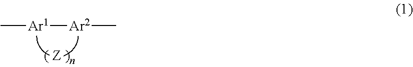
wherein, Ar¹ and Ar² are the same or mutually different and represent a tri-valent aromatic group; Z represents —O—, —S—, —C(═O)—, —CR¹R²—, —S(═O)—, —SO₂—, —Si(R³)(R⁴)—, —N(R⁵)—, —B(R⁶)—, —P(R⁷)— or P(═O)(R⁸)—; R¹, R², R³, R⁴, R⁵, R⁶, R⁷ and R⁸ are the same or mutually different and represent a hydrogen atom, a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an imide group, an imino group, an amino group, a substituted amino group, a substituted silyl group, a substituted silyloxy group, a substituted silylthio group, a substituted silylamino group, a mono-valent heterocyclic group, a heterocyclicoxy group, a heterocyclicthio group, an arylalkenyl group, an arylalkynyl group, a carboxyl group or a cyano group; n represents 1 or 2; when n is 2, two Zs may be the same or different.

7. The method according to claim 6, wherein the polymer compound is a polymer compound further containing a structural unit represented by any of the following formulae (2-1) to (2-10): 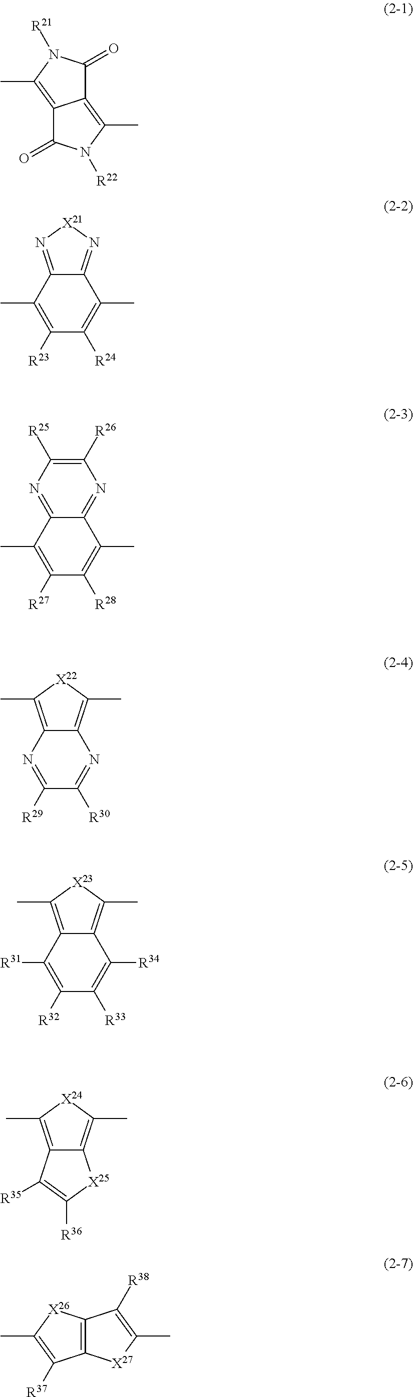 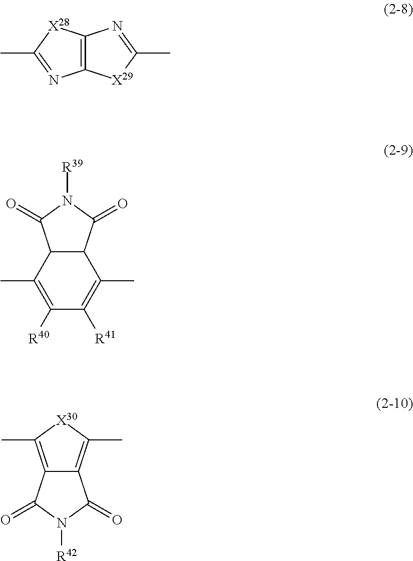
wherein, R²¹ to R⁴² represent each independently a hydrogen atom or a substituent; X²¹ to X³⁰ represent each independently a sulfur atom, an oxygen atom or a selenium atom.

8. The method according to claim 6, wherein the polymer compound is a polymer compound further containing a structural unit represented by the formula (2): 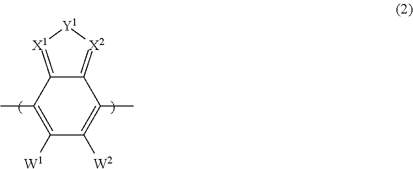
wherein, X¹ and X² are the same or mutually different and represent a nitrogen atom or ═CH—; Y¹ represents a sulfur atom, an oxygen atom, a selenium atom, —N(R⁴³)— or CR⁴⁴═CR⁴⁵—; R⁴³, R⁴⁴ and R⁴⁵ are the same or mutually different and represent a hydrogen atom or a substituent; W¹ and W² are the same or mutually different and represent a cyano group, a mono-valent organic group having a fluorine atom, a halogen atom or a hydrogen atom.

9. Use of a solution containing a polymer compound and a solvent wherein the oxygen weight concentration in the solution is 25 ppm or less, for producing an organic photoelectric conversion device.

10. The use according to claim 9, wherein the oxygen weight concentration is 10 ppm or less.

11. The use according to claim 9, wherein the oxygen weight concentration is 5 ppm or less.

12. The use according to claim 9, wherein the oxygen weight concentration is 1 ppm or less.

13. A solution containing a polymer compound and a solvent wherein the oxygen weight concentration in the solution is 25 ppm or less.

14. An organic photoelectric conversion device obtained by the method according to claim 1.
